(19) United States
(12) Patent Application Publication
(10) Pub. No.: US 2007/0230252 A1
(43) Pub. Date: Oct. 4, 2007

(54) Row selector for a semiconductor memory device

(75) Inventors: Giovanni Campardo, Bergamo (BG) (IT); Rino Micheloni, Turate (CO) (IT)

Correspondence Address: Bryan A. Santarelli, Suite. 350, 155-108th Avenue N.E., Bellevue, WA, 98004-5973, US

(73) Assignee: STMicroelectronics S.r.l.

(21) Appl. No.: 11/726,726

(22) Filed: Mar. 21, 2007

(30) Foreign Application Priority Data
Mar. 21, 2006 (EP) EP06111477.3
May 4, 2006 (EP) EP06113480.5

(51) Int. Cl. G11C 11/34; G11C 16/06

(52) U.S. Cl. 365/185.23

(57) ABSTRACT

A row selector for a semiconductor memory including a plurality of memory cells coupled to a corresponding plurality of word lines, the row selector comprising, for each word line: a first biasing circuit path adapted to bias the corresponding word line to a programming voltage when said corresponding word line is selected for selectively performing a program operation on at least one memory cell coupled to the corresponding word line, the first biasing circuit path comprising programming voltage provisioning means adapted to provide the programming voltage; a second biasing circuit path which is adapted to receive, from program-inhibit voltage provisioning means a program inhibit voltage, and to provide to the corresponding word line said program inhibit voltage when the word line is unselected during the program operation, first biasing means for driving the second biasing circuit path in order to control a conduction state thereof; wherein: said first biasing circuit path includes a first transistor controlled to be electrically conductive when the corresponding word line is selected, and to be electrically non-conductive when the corresponding word line is unselected; said first biasing means controls the second biasing circuit path to be conductive when, during the program operation, the corresponding word line is unselected, said second biasing circuit path includes a plurality of series-connected transistors, a number of transistors in said plurality being at least equal to the smallest integer not less than an absolute value of a ratio between a voltage equal to the difference between the programming voltage and the program-inhibit voltage to a predetermined maximum voltage.

### PRIORITY CLAIM

This application claims priority from European patent application Nos. EP06111477.3, filed Mar. 21, 2006, and EP06113480.5, filed May 4, 2006, which are incorporated herein by reference.

### TECHNICAL FIELD

An embodiment of the present invention relates to the field of a semiconductor memory device, and more specifically to row selectors.

### BACKGROUND

Semiconductor memory devices are commonly used to store information (either temporarily or permanently) in a number of applications; particularly, in a non-volatile memory device the information is preserved even when a power supply is off. Typically, the memory device includes a matrix of memory cells that are arranged in a plurality of rows (connected to corresponding word lines) and in a plurality of columns (connected to corresponding bit lines).

For example, flash memory devices are a particular type of non-volatile memory device, in which each memory cell is formed by a floating gate MOSFET transistor. Each memory cell has a threshold voltage (depending on the electric charge stored in the corresponding floating gate), which can be programmed to different levels representing corresponding logical values. Particularly, in a multi-level flash memory device each memory cell's threshold voltage can take more than two levels (and then store a plurality of bits).

In order to retrieve and/or store information, the flash memory device includes a decoding system that is adapted to decode an addressing code identifying a group of memory cells. In particular, the decoding system includes a row selector for selecting a corresponding word line and a column selector for selecting a corresponding set of bit lines.

Typically, the row selector of the flash memory includes low voltage predecoding circuits and high voltage decoding circuits.

The predecoding circuits operate with logical signals at low voltages, of the order of a supply voltage of the flash memory device (such as, 3V).

For this reason, the predecoding circuits may be implemented with low-voltage components that are designed in such a way to be able to sustain (between their terminals) voltage differences that have an upper limit (in absolute value) set by the supply voltage. Indeed, the low voltages that are experienced by these components allow their correct functioning, without causing breakdown thereof. For example, these components are low-voltage MOSFETs, which are designed in such a way to avoid the occurrence of gate-oxide breakdown or undesired junction breakdown when low-voltage differences on the order of the supply voltage are applied to their terminals (for example, between the gate and source terminals).

The high voltage decoding circuits (for example including level shifters for shifting the signals which are necessary for the selection of the word lines during an operation to be performed on the memory flash) apply operative voltages of high value to the selected memory cells (during program, read and erase operations). These voltages (for example, ranging from −9V to 9V) are higher (in absolute value) than the supply voltage. For example, in single supply voltage memory devices, the high voltages are generated inside the flash memory device from the supply voltage, by means of suitable circuits (such as charge pumps).

For this purpose, the high-voltage decoding circuits are implemented so as to manage the high voltages necessary during the program, read and erase operations; for example, during a program operation the row selector applies a programming voltage (such as, 9V) to the selected word line.

Therefore, the decoding circuit includes components that are designed in such a way to be able to sustain (between their terminals) voltage differences that are higher than the supply voltage (up to 9V in the cited example). For example, these components are high-voltage MOSFETs, which are MOSFETs designed in such a way to avoid the occurrence of gate-oxide breakdown or undesired junction breakdown even when high voltages (higher than the supply voltage) are applied to their terminals.

The high-voltage transistors typically have a gate oxide layer thicker than that used for the low-voltage transistors. Indeed, the thicker the gate oxide layer the higher the voltage sustained at their terminals without undesired breakdown. Since the high-voltage transistors typically occupy more silicon area compared to the low voltage transistors, the row selector occupies a significant area of a chip wherein the flash memory device is integrated.

Moreover, the use of both low- and high-voltage transistors may increase the number of processing steps and masks (for example, for differentiating the oxide thickness of the high- and low-voltage transistors); this may have detrimental impact on the manufacturing process of the flash memory device.

### SUMMARY

In its general terms, an embodiment of the present invention is based on the idea of using components working at reduced voltage.

In detail, an embodiment of the present invention proposes a row selector for a semiconductor memory. The semiconductor memory includes a plurality of memory cells coupled to a corresponding plurality of word lines. The row selector comprises for each word line: a first biasing circuit path adapted to bias the corresponding word line to a programming voltage when said corresponding word line is selected for selectively performing a program operation on at least one memory cell coupled to the corresponding word line, the first biasing circuit path comprising programming voltage provisioning means adapted to provide the programming voltage; a second biasing circuit path which is adapted to receive, from program-inhibit voltage provisioning means a program inhibit voltage, and to provide to the corresponding word line said program inhibit voltage when the word line is unselected during the program operation, first biasing means for driving the second biasing circuit path in order to control a conduction state thereof; wherein said first biasing circuit path includes a first transistor controlled to be electrically conductive when the corresponding word line is selected, and to be electrically non-conductive when the corresponding word line is unselected; said first biasing means controls the second biasing circuit path to be conductive when, during the program operation, the corresponding word line is unselected. The second biasing circuit path includes a plurality of series-connected transistors, a number of transistors in said plurality being at least equal to the smallest integer not less than an absolute value of a ratio between a voltage equal to the difference between the programming voltage and the program-inhibit voltage to a predetermined maximum voltage.

### BRIEF DESCRIPTION OF THE DRAWINGS

Features and advantages of one or more embodiment of the present invention will be made apparent by the following detailed description of one or more embodiments thereof, provided merely by way of non-limitative, description that will be conducted making reference to the attached drawings.

FIG. 1 is a schematic block diagram of a memory device in which the solution according to an embodiment of the invention can be used.

FIG. 2 schematically shows a row selector according to an embodiment of the present invention.

FIG. 3A schematically shows the row selector of FIG. 2 during a program operation according to an embodiment of the present invention.

FIG. 3B schematically shows the row selector of FIG. 2 during a read operation according to an embodiment of the present invention.

FIG. 3C schematically shows the row selector of FIG. 2 during an erasing operation according to an embodiment of the present invention.

FIG. 4 is an exemplary implementation of a single word line selector block of the row selector of FIG. 2 according to an embodiment of the invention.

FIG. 5 shows a table listing voltage values of some internal nodes of the single word line selector block of FIG. 4 during the operation thereof according to an embodiment of the invention.

FIG. 6 schematically shows an exemplary implementation of a first biasing block of the row selector of FIG. 2 according to an embodiment of the invention.

FIG. 7 shows a table listing voltage values of the some internal nodes of the first biasing block of FIG. 6 during the operation thereof according to an embodiment of the invention.

FIG. 8 is an exemplary implementation of a second biasing block of the row selector of FIG. 2 according to an embodiment of the invention.

FIG. 9 shows a table listing voltage values of some internal nodes of the second biasing block of the FIG. 8 during the operation thereof according to an embodiment of the invention.

### DETAILED DESCRIPTION

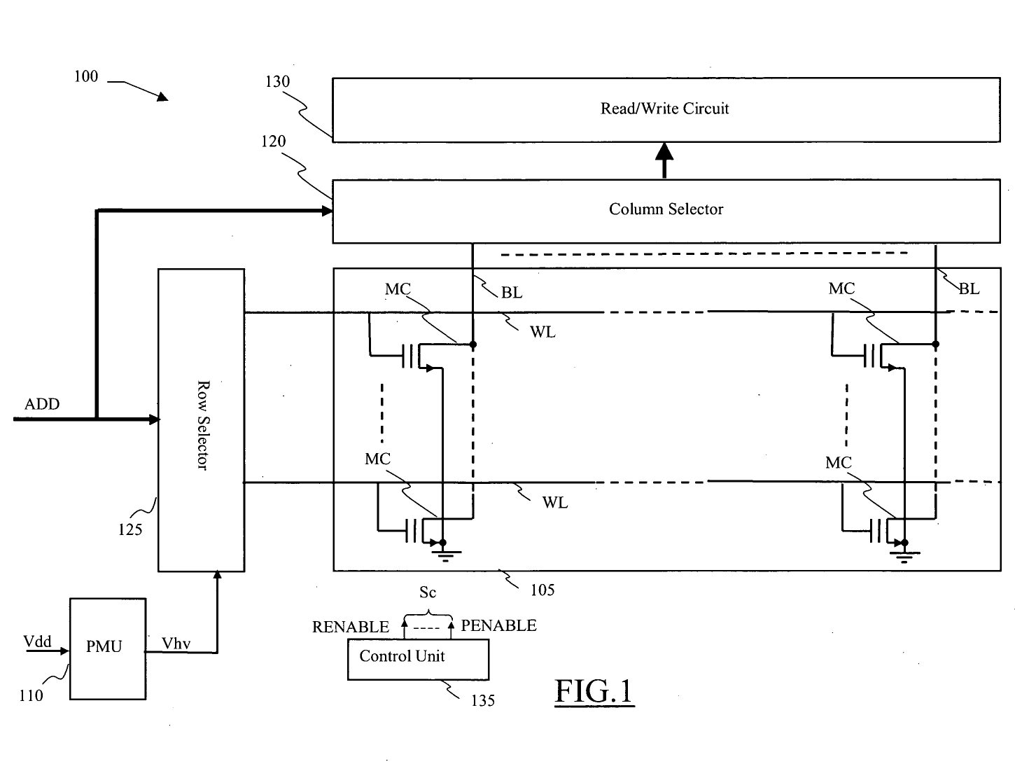

Referring to FIG. 1, a flash memory device 100 is schematically represented according to an embodiment of the invention. The memory device 100 includes one or more sectors 105 (only one shown in the Figure). The sector 105 includes a plurality of memory cells MC, each one including a floating gate MOSFET. In particular, the memory device 100 is of the flash type, and an erase operation affects all the memory cells MC of the generic sector 105.

In an erased condition each memory cell MC has a low threshold voltage (to which a logic level “1” is typically associated). The memory cell MC is programmed by injecting electrons into its floating-gate; in this condition the memory cell MC has a high threshold voltage (to which a logic level “0” is typically associated).

In each sector 105, the memory cells MC are arranged in rows and columns. The memory cells MC of each column have the drain terminals connected to a respective bit line BL, while the memory cells MC of each row have the control terminals connected to a respective word line WL. The source terminal of each memory cell MC receives a reference voltage GND (or ground) (alternatively, the source terminals of all the memory cells MC of a same sector are connected to a common source line, whose voltage may be properly varied depending on the operation to be performed).

The memory device 100 further includes a PMU (acronym for Power Management Unit) 110. The PMU 110 provides the biasing voltages that are used for performing the conventional operations (such as read, program, erase and verify) on the memory device 100. The PMU 110 receives a supply voltage Vdd (such as 3V) from the outside of the memory device, and outputs different operative voltages Vhv; the operative voltages Vhv are generally higher in absolute value than the supply voltage Vdd, for example, ranging from −9V to 9V. For this purpose, the PMU 110 includes a circuitry (e.g., charge pumps) adapted to generate the operative voltages Vhv from the supply voltage Vdd. Preferably, those charge pumps are implemented by means of low voltage transistors only, as described in Patent Application No. EP05111284.5 filed on 25 Nov. 2005 in the name of the present Applicant (the entire disclosure of which is herein incorporated by reference).

The memory device 100 receives an addressing code ADD for accessing the memory cells MC. The addressing code ADD includes a set of bits (such as 32). A portion of the addressing code ADD is supplied to a column selector 120, which selects a set of desired bit lines BL (such as 8 or 16 bit lines at a time). Another portion of the addressing code ADD is supplied to a row selector 125, which selects one desired word line WL at a time.

The column selector 120 couples the selected bit lines BL to a read-write circuit 130. The read/write circuit 130 includes all the components (e.g., sense amplifiers, comparators, reference current/voltage generators, pulse generators, program load circuits and the like), which are normally required for writing the desired logic values into the selected memory cells MC and for reading the logic values currently stored therein. The read/write circuit 130 is coupled to externally-accessible terminals of the memory device 100 (not shown in figure) for receiving/delivering data.

The row selector 125 receives the corresponding portion of the addressing code ADD and the operative voltages Vhv. According to the operation to be performed on the memory device 100, the row selector 125 biases the word lines of the sector 105 to one or more operative voltages Vhv or the supply voltage Vdd or ground. For example, during a programming operation the row selector 125 biases a selected word line to one of the operative voltages Vhv, such as a programming voltage POSV (for example, POSV=9V), whereas the remaining word lines are brought to the reference voltage GND. During an erasing operation, the row selector 125 biases all the word lines WL of the sector 105 to a different operative voltage Vhv, such as an erasing voltage NEGV (for example, NEGV=−9V). During a read operation, the row selector 125 biases a selected word line to one of the operative voltages Vhv, such as a reading voltage (for example, of 6V), whereas the remaining word lines are brought to the reference voltage GND.

The memory device 100 includes a control unit 135 which is adapted to provide control signals (denoted as whole as Sc) which are used for driving the components of the memory device during the operation thereof. For example, in order to perform the various operations on the memory cells MC of the memory device 100, the control signals Sc include a programming enable signal PENABLE which controls the program operation and a reading enable signal RENABLE which controls the reading operation.

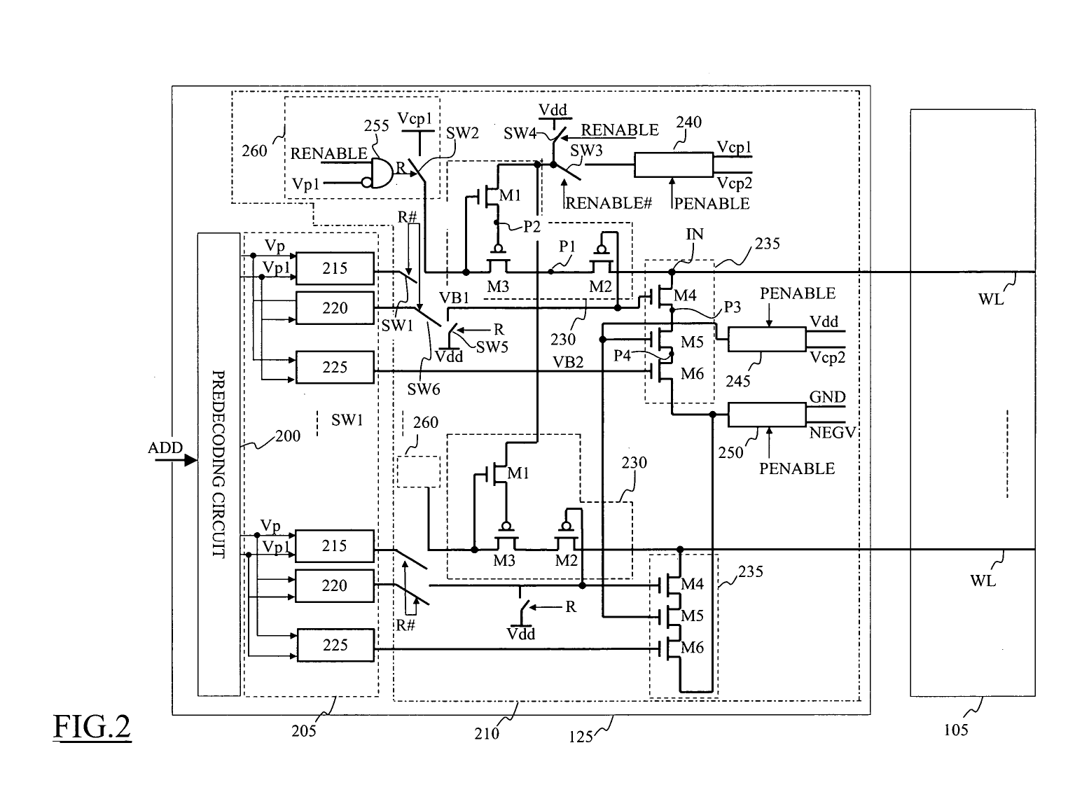

Referring to FIG. 2, a schematic implementation of the row selector 125 is shown. The row selector 125 includes a predecoding circuit 200, which receives the corresponding portion of the addressing code ADD and generates a first (logical) selection signal Vp and a second (logical) selection signal Vp1 for each word line WL.

Moreover, the row selector 125 includes a decoding circuit 205 which is coupled to the word lines of the sector 105 by means of an intermediate circuitry 210. The intermediate circuitry 210 receives from the decoding circuit 205 one or more operative voltages Vhv and in response is able to bias one or more word lines WL of the sector 105 according to the operation to be performed on the memory device.

In more detail, the decoding circuit 205 includes for each word line WL of the sector 105 a single word line selector block 215, which selects a corresponding word line during the operation of the memory device. In particular, each single word-line selector block 215 receives the corresponding first selection signal Vp and the second selection signal Vp1 and according to the assertion state thereof biases, by means of the intermediate circuitry 210, the corresponding word line WL to one of the operative voltages Vhv.

Moreover, for each word line WL of the sector 105, the decoding circuit 205 includes a first biasing block 220 and a second biasing block 225 that are adapted for biasing one or more corresponding electronic components included in the intermediate circuitry 210. The first biasing block 220 and the second biasing block 225 receive as well the corresponding first selection signal Vp and the second selection signal Vp1.

The intermediate circuitry 210 includes for each word line WL a first circuital structure 230 and a second circuital structure 235. The first circuital structure 230 is adapted for coupling the word line WL to the corresponding single word line selector block 215 whereas the second circuital structure 235 is a circuit branch controlled by the first biasing block 220 and the second biasing block 225.

The first circuital structure 230 includes a n-channel MOSFET M1 and two p-channel MOSFETs M2 and M3. The transistors M2 and M3 are connected in series, in particular the transistor M3 has a first terminal adapted to be coupled to an output terminal of the corresponding single word-line selector block 215 through a first switch SW1. Depending on the operation to be conducted, the first terminal of the transistor M3, in alternative to being coupled to the single word line selector block 215, is adapted to receive one of the operative voltage Vhv (for example, a first biasing voltage Vcp1) through a first reading circuit 260. For example, the first biasing voltage Vcp1 is a voltage of approximately 6V, used for biasing a word line containing a memory cell to be read.

In detail, the first reading circuit 260 includes a second switch SW2 controlled by an enabling signal R, generated by an AND gate 255 which receives a complemented second selection signal Vp1# and the reading enable signal RENABLE. The first switch SW1 is enabled by a complemented enabling signal R#. In other words, when the complemented enabling signal R# is asserted (to the supply voltage Vdd) the first switch SW1 is closed.

A second terminal (denoted as node P1) of the transistor M3 is connected to the first terminal of the transistor M2. The transistor M2 has the second terminal (denoted as intermediate node IN) which is coupled to the corresponding word line WL. The control terminal of the transistor M3 is connected to the second terminal of the transistor M1 (denoted as node P2), whereas the first terminal of the transistor M3 is connected to the control terminal of the transistor M1. The first terminal of the transistor M1 receives one of operative voltages Vhv by means of a first voltage switch 240. In particular, the first terminal of the transistor M1 is coupled to the first voltage switch 240 through a third switch SW3, controlled by the complemented reading enable signal RENABLE#. Moreover, the first terminal of the transistor M1 is adapted to receive the supply voltage Vdd trough a fourth switch SW4 controlled by the reading enable signal RENABLE.

The first voltage switch 240 is a circuit adapted to selectively connect one input terminal, selected among two its input terminals each one adapted to receive a respective operative voltage Vhv (for example, the first biasing voltage Vcp1=6V and a second biasing voltage Vcp2=−6V), to a switch output terminal which is connected (when the third switch SW3 is closed) to the first terminal of the transistor M1. The first voltage switch 240 receives the program enable signal PENABLE and according to assertion state thereof selects the desired input terminal which is to be coupled to the first terminal of the transistor M1. More in particular, when the program enable signal PENABLE is asserted (at the supply voltage Vdd), the first voltage switch 240 provides at the output the first biasing voltage Vcp1; vice versa the first voltage switch 240 provides at the output the second biasing voltage Vcp2. Preferably, the voltage switch 240 is implemented by means of low-voltage transistors only, as described in the co-pending Patent Application No. EP06111477.3 filed on 21 Mar. 2006, (the entire disclosure of which is herein incorporated by reference).

The second circuital structure 235 is a circuit branch including three n-channel MOSFETs M4, M5 and M6 in series. More in particular, the transistor M4 has the second terminal connected to the second terminal of the transistor M2 (i.e., the intermediate node IN) and the first terminal connected to the second terminal of the transistor M5 (denotes as node P3). The transistor M5 has the first terminal connected to the second terminal of the transistor M6 (denoted as node P4) and the control terminal connected to a second voltage switch 245. The second voltage switch 245 is a circuit adapted to selectively connect one between two input terminals thereof to a switch output terminal which is connected to the control terminal of the transistor M5. In particular, one input terminal is adapted to receive a corresponding operative voltage Vhv (for example, the second biasing voltage Vcp2=−6V) whereas the other one is adapted to receive the supply voltage Vdd. The second voltage switch 245 receives the program enable signal PENABLE and, according to assertion state thereof, selects the desired input terminal whose voltage is to be made available at the output. More in particular, when the program enable signal PENABLE is asserted (at the supply voltage Vdd), the second voltage switch 245 provides the supply voltage Vdd at the output; vice versa the second voltage switch 245 provides the second biasing voltage Vcp2.

The transistor M6 has the first terminal connected to a switch output terminal of a third voltage switch 250. The third voltage switch 250 has one input terminal which receives a corresponding operative voltage Vhv (for example, the erasing voltage NEGV=−9V) whereas the other one receives the reference voltage GND. Similarly to the voltage switches 240 and 245, the voltage switch 250 receives the program enable signal PENABLE that commands the coupling of the desired input terminal to the first terminal of the transistor M6. In particular, when the program enable signal PENABLE is asserted (at the supply voltage Vdd) the third voltage switch 250 provides the reference voltage GND; on the contrary, the third voltage switch 250 provides the erasing voltage NEGV.

Moreover, the control terminal of the transistor M4 is connected to a fifth switch SW5 controlled by the enabling signal R and a sixth switch SW6 controlled by the complemented enabling signal R#. In particular, when the enabling signal R is asserted (at the supply voltage Vdd) the switch SW5 is closed and the sixth switch SW6 is open.

The control terminal of the transistor M6 receives from the second biasing block 220 a second control signal VB2.

As can be noted, the intermediate circuitry 210 includes the above described first and second circuit structures for each word line.

During the program operation, the memory device receives the addressing code for accessing the memory cell(s) to be programmed. In particular, for selecting the word line, the corresponding first selection signal Vp is asserted (at the supply voltage Vdd) whereas the corresponding second selection signal Vp1 is de-asserted (at the reference voltage GND). For the remaining unselected word lines the corresponding first and second selection signals Vp and Vp1 are both asserted. At the same time, the control unit 135 asserts the programming enable signal PENABLE and deasserts the reading enable signal RENABLE. The switch SW4 is open, whereas the switch SW3 is closed; the enabling signal R is deasserted (at the reference voltage GND), so the switches SW1, SW6 are closed and the switches SW2 and SW5 are open.

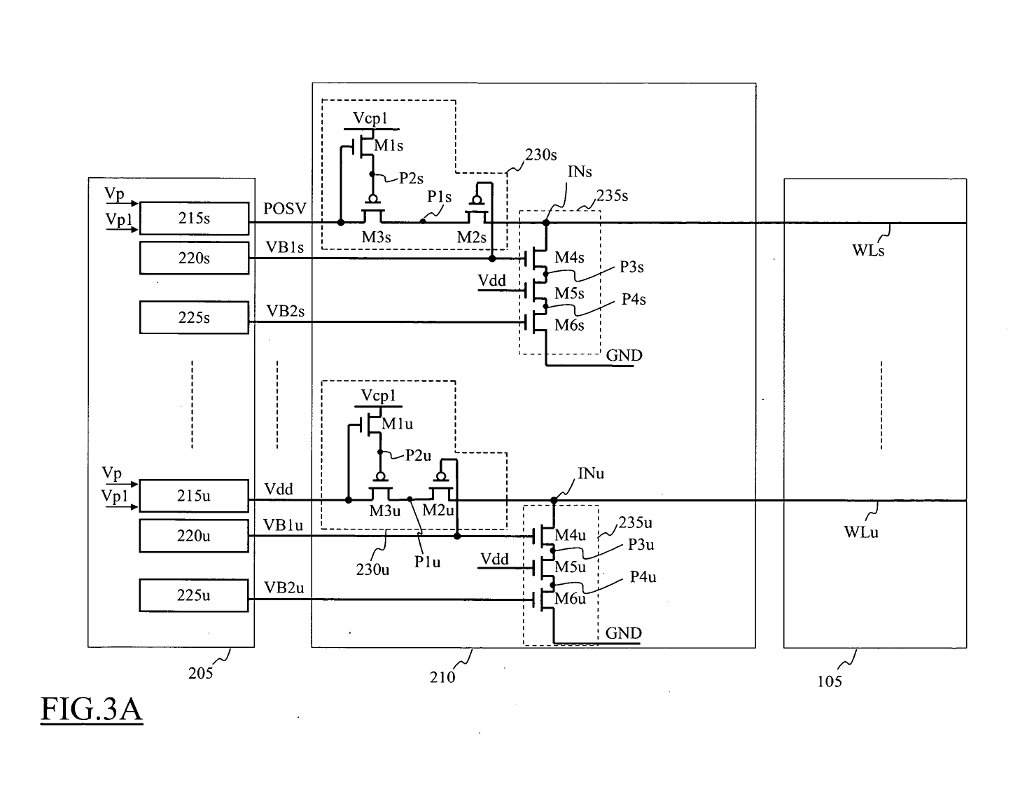

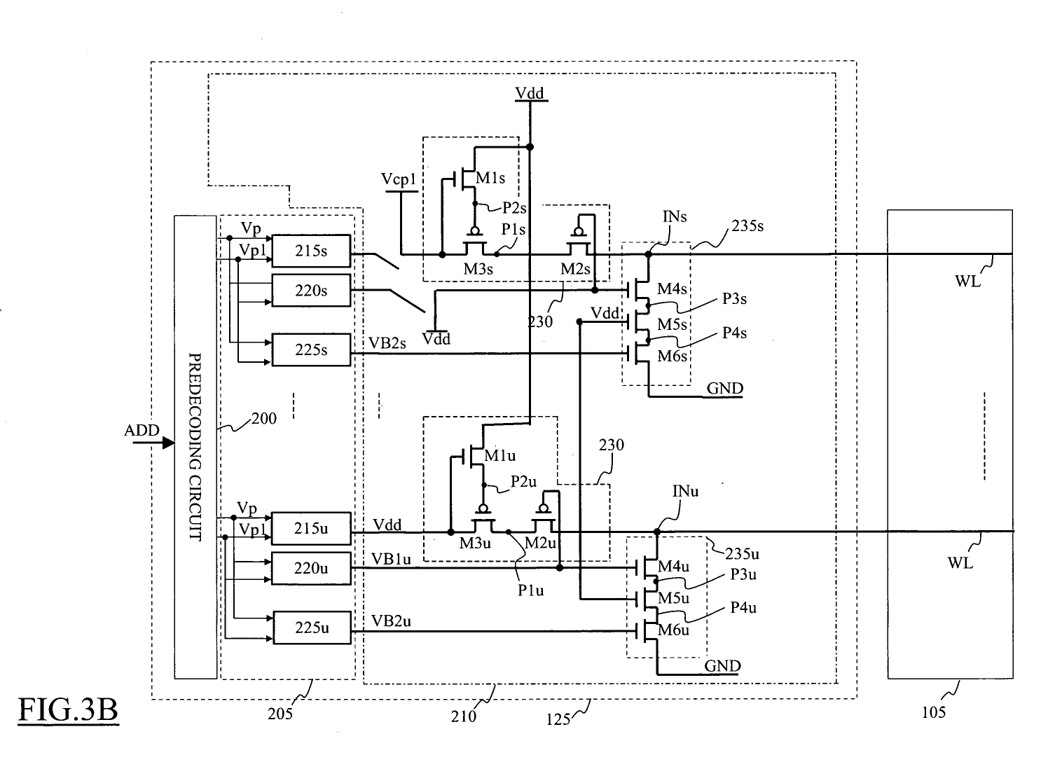

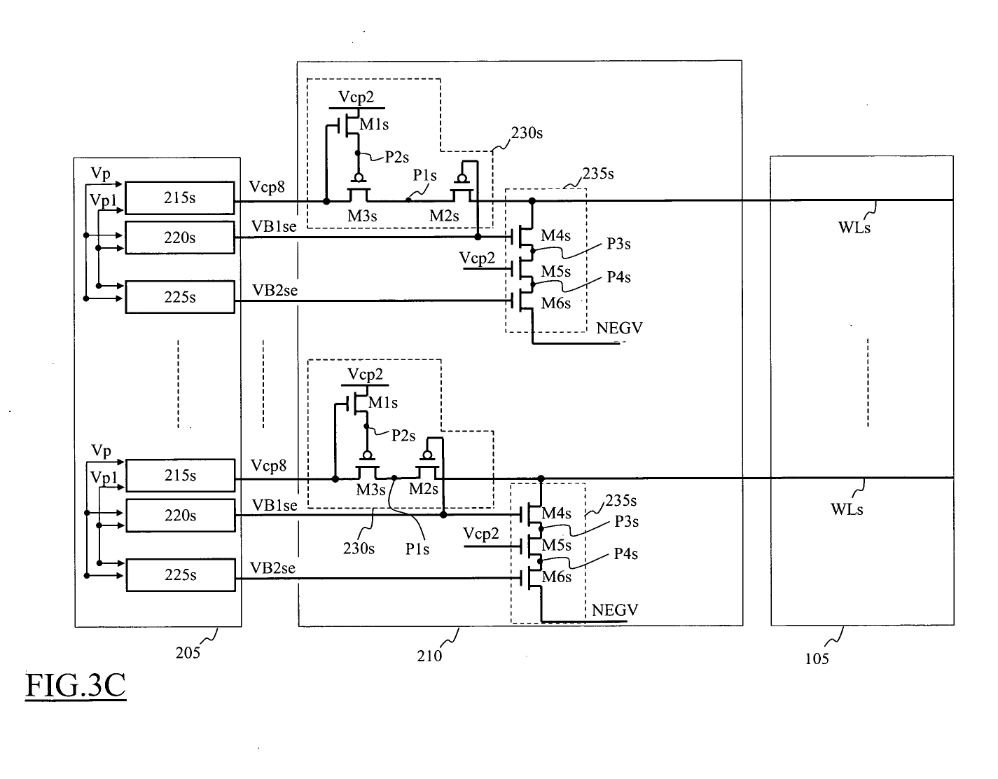

As above discussed, the row selector 125 is able to select the desired word line WL and to bias it at the proper voltage in order to perform the program operation. For this purpose, as shown in FIG. 3A, two word lines are considered: a selected word line WLs and an unselected word line WLu (from now on, the suffixes “s” and “u” will be appended to all references of the components included in the row selector 125 to discriminate those associated or related to selected word lines from those associated or related to unselected word lines). Moreover, in all the embodiments illustrated in the following, both the p-channel MOSFETs and the n-channel MOSFETs included in the row selector 125 are assumed to have a threshold voltage of 1 Volt (in absolute value), and the supply voltage Vdd is assumed to be equal to 3 Volts with respect to the reference voltage GND.

The single word line selector block 215s associated with the selected word line and responsive to the selection signals Vp and Vp1 provides one of the operative voltages Vhv such as the programming voltage POSV (for example, POSV=9V) to the intermediate circuit 210. In particular, the programming voltage POSV is provided to the first terminal of the transistor M3s and to the control terminal of the transistor M1s. Moreover, since the program control signal PENABLE is asserted, the first terminal of the transistor M1s receives the first biasing voltage Vcp1 (for example, Vcp1 =6V) by means of the first voltage switch 240.

The second circuital structure 235s receives by means of the first and the second biasing blocks 220s and 225s the first and second control signals VB1 and VB2 at the voltages VB1s and VB2s, respectively. For example, VB1s=6V and VB2s=0V.

Moreover, since the program control signal PENABLE is asserted, by means of the corresponding second and third voltage switches 245 and 250, the transistor M5s receives at its control terminal the supply voltage Vdd and the transistor M6s receives to its first terminal the reference voltage GND.

During operation, the intermediate node INs is brought to the programming voltage POSV. More in particular, the transistor M1s is turned on since its driving voltage (between the control and first terminal) is equal to the supply voltage Vdd. On the other hand, the transistor M1s does not conduct any current since it is connected in series to the control terminal of the transistor M3s which has a significantly high resistance. Thus, the voltage of the node P2s (and consequently the voltage of the control terminal of the transistor M3s) reaches the biasing operative voltage Vcp1 (in the example at issue, 6V). In such a way, the transistor M3s is turned on (because its driving voltage between the terminal coupled to the block 215, and the control terminal is equal to the supply voltage Vdd), and the node P1s is brought to the programming voltage POSV. In this biasing condition, the transistor M2s is turned on as well (because its driving voltage, equal to the difference between the voltage VB1s and the voltage POSV is equal to the supply voltage Vdd), thus biasing the selected word line WLs to the programming voltage POSV. In other words, the first circuital structure 230s forms a conductive path which is adapted for biasing the selected word line WLs at the programming voltage POSV.

In the second circuital structure 235s, the transistor M6s is turned off since its driving voltage is equal to zero (the voltage VB2s is equal to ground). The transistors M4s and M5s are connected in series to the transistor M6s, thus both the transistors M4s and M5s cannot conduct any current because the transistor M6s is turned off. In this biasing condition, the transistors M4s, M5s and M6s do not interfere with the voltage of the intermediate node INs. In other words, the transistors M4s, M5s and M6s form a path with a significant high resistance, thus allowing to insulate the intermediate node INs from the reference voltage GND.

More in detail, the voltage of the node P3s is at most equal to the voltage of first control signal VB1 (i.e., in the example, the voltage VB1s=6V) minus the threshold voltage of the transistor M4s (in the example at issue, 6−1 =5V), otherwise the transistor M4s should be conductive. Likewise, the voltage of the node P4s is at most equal to the supply voltage Vdd minus the threshold voltage thereof (in the example at issue, 3−1=2V), otherwise the transistor M5s should be conductive.

Therefore, the transistors M1s, M2s and M3s of the first circuital structure 230s and the transistors M4s, M5s and M6s of the second circuital structure 235s sustain between their control and first/second terminals a voltage difference at most equal to the supply voltage Vdd. In other words, the transistors M1s-M6s are low-voltage-type transistors (i.e., the circuital structures 230s and 235s may be implemented with low-voltage transistors only, without having to use high-voltage transistors).

Referring now to unselected word line WLu, the remaining word line selector block 215u provides the supply voltage Vdd to the intermediate circuit 210 (and thus to the corresponding first terminal of the transistor M3u of the first circuital structure 230u). In this case the first and the second selection signals Vp and Vp1 are asserted (both are at the supply voltage Vdd).

The second circuital structure 235u receives the control signals VB1 and VB2 at the voltages VB1u and VB2u, respectively. For example, VB1u=VB2u=3V.

Moreover, since the program control signal PENABLE is asserted, the first terminal of the transistor M1u receives the first biasing voltage Vcp1 by means of the first voltage switch 240. Likewise, by means of the corresponding voltage switches 245 and 250, the transistor M5u receives at its control terminal the supply voltage Vdd and the transistor M6u receives to its first terminal the reference voltage GND.

During the program operation, the intermediate node INu (and thus the unselected word line WLu) is brought to the reference voltage GND. For this purpose, the second biasing block 225u provides the second control signal VB2 at the value (in the example, VB2u=3V) adapted to turn on the transistor M6u of the second circuital structure 235u (in such a way, the transistor M6u has its driving voltage equal to the supply voltage Vdd). In this case, the node P4u reaches approximately the reference voltage GND, thereby allowing to the transistor M5u to turn on (since its driving voltage is equal to the supply voltage Vdd). Thus, the node P3u reaches the reference voltage GND. The transistor M4u is turned on (since its driving voltage is equal to the supply voltage Vdd, being the voltage VB1u equal to 3V, in this example) so as to bring the intermediate node INu to the reference voltage GND. In other words, the second circuital structure 235u forms a conductive path which is adapted to bring the unselected word line WLu to ground.

Also in this case, the transistors M4u, M5u and M6u sustain between their control and first/second terminals a voltage difference at most equal to the supply voltage Vdd. In other words, the transistors M4u, M5u and M6u can be low-voltage-type transistors.

Moving to the first circuital structure 230u, the transistor M2u is turned off (since its driving voltage is higher than its threshold voltage), thereby isolating the intermediate node INu from the voltage provided by the single word line selector block 215u. The transistor M2u is connected in series to the transistor M3u. In such a way, the transistor M3u cannot conduct any current and the first circuital structure 230u is adapted to form a path with a significant high resistance. The transistor M1u is turned off, because its driving voltage is lower than threshold voltage thereof.

Also in this case, the voltage differences sustained across the terminals of all transistors included in the first circuital structure 230u are at most equal to the supply voltage Vdd. Therefore, the transistors M1u, M2u and M3u can be low-voltage-type transistors.

Therefore, thanks to the row-selector structure described above, it is possible to avoid the use of high-voltage transistors having relatively thick oxide layers (capable of sustaining across their terminals voltages higher than the supply voltage Vdd). This may significantly reduce the area occupied by the memory device and the number of processing steps and masks of the manufacturing process of the memory device.

Moving to FIG. 3B, during a reading operation, the control unit 135 asserts the reading enable signal RENABLE and the programming enable signal PENABLE. In this biasing condition, the first terminals of the transistors M1s and M1u and the control terminal of the transistor M4s (related to selected word line WLs) receive the supply voltage Vdd. Moreover, the first terminal of the transistor M3s receives the first operative voltage Vcp1 (in the example at issue equal to 6V).

In this biasing condition, the transistor M1s is turned on (since its driving voltage is equal to the supply voltage Vdd) thereby the node P2s is brought to the supply voltage Vdd. In such a way, the transistor M3s is turned on (since its driving voltage is equal to the supply voltage Vdd), so that the node P1s is brought to the first operative voltage Vcp1. The transistor M2s is turned on, so that the intermediate node INs reaches the first operative voltage Vcp1. Similarly to the program operation, the second circuital structure 235s forms a non-conductive path, because the transistor M6s is turned off, with the nodes P3s and P4s which can reach at most the supply voltage Vdd minus the threshold voltage of the transistor M4s and M5s, respectively.

As in the program operation, the second circuital structure 235u forms a conductive path, so the word line WLu is brought to the reference voltage GND. Concerning the first circuital structure 230u, the transistor M2u is turned off (since its driving voltage is higher than its threshold voltage), thereby isolating the intermediate node INu from the voltage provided by the single word line selector block 215u. The transistor M2u is connected in series to the transistor M3u, which cannot conduct any current, and the first circuital structure 230u is adapted to form a high-resistance path. The transistor M1u is turned off (since its driving voltage is lower than threshold voltage thereof). Also in this case, all the transistors sustain voltage differences (between the control terminal and other terminals thereof) at most equal to the supply voltage Vdd.

During the erasing operation, the whole selected memory sector 105 is erased. For selecting all the word lines of the sector to be erased, each of the first selection signals Vp and each of the second selection signals Vp1 corresponding to the word lines of the sector are deasserted (at the reference voltage GND). At the same time, the control unit 135 deasserts the program enable signal PENABLE and the reading enable signal RENABLE.

In other words, as shown in FIG. 3C, the row selector 125 selects all the word lines (for this reason all the word lines in the sector are denoted with the reference WLs), and biases them to the erasing voltage NEGV (in the example at issue, NEGV=−9V).

Since the program control signal PENABLE is deasserted, each transistor M1s receives to its first terminal the second biasing voltage Vcp2 (for example, Vcp2=−6V) through the first voltage switch 240. Likewise, the second and third voltage switches 245 and 250 provide to the control terminal of each transistor M5s and to the first terminal of each transistor M6s the second biasing voltage Vcp2 (e.g., Vcp2=−6V) and the erasing voltage NEGV (e.g., NEGV=−9V), respectively. The first and second control signals VB1 and VB2 reach values VB1se and VB2se (for example, VB1se=VB2se=−6V). Moreover, each single word line selector block 215s provides to the first terminal of the associated transistor M3s one of the operative voltages, for example a voltage Vcp8 (for example, Vcp8=−6V).

In this biasing condition, each second circuital structure 235s forms a conductive path that brings the corresponding word line to the erasing voltage NEGV. In particular, the transistor M6s is turned on (since its driving voltage is higher than its threshold voltage). In such a way, the node P4s reaches approximately the erasing voltage NEGV, thus turning on the transistor M5s. In such a way, the node P3s reaches the erasing voltage NEGV, so that also the transistor M4s is turned on, and the intermediate node INs is thus brought to the erasing voltage NEGV.

As can be noted, the transistors M4s, M5s and M6s sustain a voltage differences (between the control terminal and any other terminals thereof) at most equal to the supply voltage Vdd, so they can be low voltage transistors.

Moving to the first circuital structure 230s, the transistor M2s is turned off (since its driving voltage is higher than its threshold voltage). The transistor M2s is connected in series to the transistor M3s, which cannot conduct any current, and the first circuital structure 230s is adapted to form a high-resistance path, thereby insulating the intermediate node INs from the voltage provided through the corresponding single word line block selector 215s. Also in this case, the voltage differences sustained at the terminals of all transistors included in the first circuital structure 230s are at most equal to the supply voltage Vdd and the transistors M1s, M2s and M3s can be low-voltage transistors (with advantages such as those discussed in the foregoing).

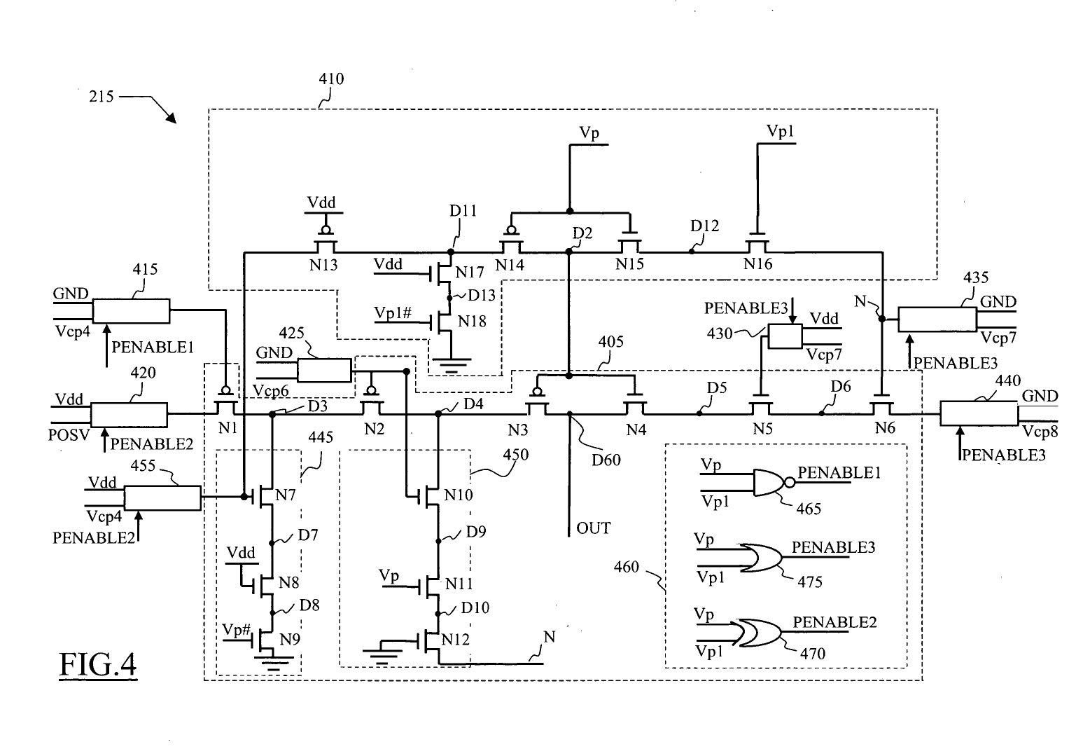

Referring to FIG. 4, an exemplary implementation of a generic single-word-line selector block 215 is schematically shown. The single-word-line selector block 215 includes a first and a second circuital blocks 405 and 410.

The first circuital block 405 includes a first circuit branch with three p-channel MOSFETs N1, N2 and N3 connected in series, and a second circuit branch with three further series-connected n-channel MOSFETs N4, N5 and N6, the first and second circuit branches being both connected to a common node D60. In particular, the transistor N1 has the control terminal connected to an output terminal of a fourth voltage switch 415 and a first terminal connected to an output terminal of a fifth voltage switch 420. The fourth voltage switch 415, having two input terminals each one adapted to receive one of the operative voltages Vhv (for example, a fourth biasing voltage Vcp4=6V) and the reference voltage GND respectively, selectively connects one of its input terminals to the control terminal of the transistor N1, according to the operation to be performed on the memory device. The voltage switch 415 receives a first control signal PENABLE1 that, according to its assertion state, causes the selection of a corresponding switch input terminal. In particular, when the control signal PENABLE1 is asserted (at the supply voltage Vdd), the voltage switch 415 provides at the switch output the operative voltage Vcp4; on the contrary, the voltage switch 415 provides the reference voltage GND.

Likewise, the fifth voltage switch 420, having two input terminals each one adapted to receive one of the operative voltages Vhv (for example, the programming voltage POSV) and the supply voltage Vdd, selectively connects one of its input terminals to the first terminal of the transistor N1 according to the operation to be performed on the memory device. The voltage switch 420 receives a second control signal PENABLE2, whose assertion state causes the selection of either one of the switch input terminals. In particular, when the control signal PENABLE2 is asserted (at the supply voltage Vdd), the voltage switch 420 provides at the switch output the programming voltage POSV; on the contrary, the voltage switch 420 provides the supply voltage Vdd.

The second terminal of the transistor NI (denoted as node D3) is connected to a first terminal of the transistor N2, which has the second terminal (denoted as node D4) connected to a second terminal of the transistor N3. A sixth voltage switch 425 is adapted for driving the transistor N2. In particular, the control terminal of the transistor N2 is connected to an output terminal of the voltage switch 425. The voltage switch 425 has two input terminals each one adapted to receive an operative voltage Vhv (for example, the fourth biasing voltage Vcp4=6V) and the reference voltage GND, respectively; moreover, the voltage switch 425 receives the second control signal PENABLE2. Each one of the input terminals of the voltage switch 425 is adapted to be connected to the switch output terminal, and, according to the assertion state of the control signal PENABLE2, the transistor N2 can alternatively be driven by the operative voltage Vcp4 or the reference voltage GND. The first terminal of the transistor N3 is connected to the node D60; the node D60 is connected to an output terminal of the word-line-selector block 215, which is adapted for providing a word-line-selecting signal OUT. The node D60 is also connected to a second terminal of the transistor N4, which has the control terminal connected to the control terminal of the transistor N3. Moreover, the transistor N4 has a first terminal (denoted as node D5) connected to a second terminal of the transistor N5. The transistor N5 has a control terminal which is connected to an output terminal of a seventh voltage switch 430. The voltage switch 430 has two input terminals which receive a respective operative voltage Vhv, for example, the seventh biasing voltage Vcp7=−3V and the supply voltage Vdd, respectively. Moreover, the seventh voltage switch 430 receives a third control signal PENABLE3 that, according to its assertion state, causes the connection of one of the switch input terminals to the switch output terminal, thereby the transistor N5 can be alternatively driven by the operative voltage Vcp7 or the supply voltage Vdd. In particular, when the third control signal PENABLE3 is asserted, the voltage switch 430 provides the supply voltage Vdd; vice versa, the voltage switch 430 provides the operative voltages Vcp7.

A first terminal of the transistor N5 (denoted as node D6) is connected to a second terminal of the transistor N6. A control terminal of the transistor N6 is connected to an output terminal of an eighth voltage switch 435. The voltage switch 435 has two input terminals each one adapted to receive one of the operative voltages Vhv, for example, the seventh biasing voltage Vcp7 and the reference voltage GND, respectively. Similarly to the voltage switch 430, the voltage switch 435 receives the third control signal PENABLE3 that, according to its assertion state, causes the switch to connect one of its input terminals to the output terminal thereof, thereby the transistor N6 can be alternatively driven by the operative voltage Vcp7 or the reference voltage GND. In particular, when the third control signal PENABLE3 is asserted, the voltage switch 435 provides the reference voltage GND; on the contrary, the voltage switch 435 provides the operative voltages Vcp7.

A first terminal of the transistor N6 is connected to a ninth voltage switch 440. The voltage switch 440 has two input terminals, one of which receives one of the operative voltages Vhv, for example, the voltage Vcp8=−6V, and the other one receives the reference voltage GND. Each one of the input terminals of the voltage switch 440 is alternatively connected to the switch output terminal according to the assertion state of the control signal PENABLE3, thus allowing to bring the first terminal the transistor N6 at the operative voltage Vcp8 or at the reference voltage GND. In particular, when the third control signal PENABLE3 is asserted, the voltage switch 440 provides at the switch output the reference voltage GND; on the contrary, when PENABLE3 is not asserted, the voltage switch 440 provides the operative voltages Vcp8.

The first circuital block 405 further comprises two circuital structures 445 and 450.

In detail, the circuital structure 445 includes three n-channel MOSFETs N7, N8 and N9 which are connected in cascade. In particular, the transistor N7 has a second terminal connected to the second terminal of the transistor N1, and the first terminal (denoted as node D7) connected to a second terminal of the transistor N8. The transistor N7 has a control terminal which is connected to an output terminal of a tenth voltage switch 455. The voltage switch 455 has two input terminals, respectively adapted to receive the fourth biasing voltage Vcp4=6V and the supply voltage Vdd. The voltage switch 455 is controlled by the second control signal PENABLE2, and according to the assertion state thereof, one of the switch input terminals is connected to the switch output terminal, so that the control terminal of the transistor N7 can be alternatively biased at the operative voltage Vcp4 or at the supply voltage vdd. The transistor N8 has a first terminal (denoted as node D8) connected to a second terminal of the transistor N9 and a control terminal which is adapted to receive the supply voltage Vdd. The transistor N9 has a first terminal connected to ground, whereas its control terminal receives a complemented first selection signal Vp#.

The circuital structure 450 includes three n-channel MOSFETs N10, N11 and N12 connected in cascade. In particular, the transistor N10 has a second terminal connected to the node D4, and a first terminal (denoted as node D9) connected to a second terminal of the transistor N11. The transistor N10 has a control terminal connected to the output terminal of the voltage switch 425. The transistor N11 has a first terminal (denoted as node D10) connected to a second terminal of the transistor N12 and a control terminal adapted to receive the first selection signal Vp. The transistor N12 has a first terminal connected to the output terminal (denoted as node N) of the fifth voltage switch 435 and a control terminal that receives the reference voltage GND.

The first circuital block 405 has an output terminal D2 that is connected to the control terminal of the transistors N3 and N4.

The second circuital block 410 includes a first circuit branch with two p-channel MOSFETs N13 and N14 connected in series, and a second circuit branch with two further series-connected n-channel MOSFETs N15 and N16, the first and second circuit branches being both connected to the common node D2. In particular, the transistor N13 has a first terminal connected to the output terminal of the voltage switch 455 and a control terminal which receives the supply voltage Vdd. The second terminal (denoted as node D11) of the transistor N13 is connected to a first terminal of the transistor N14. The transistor N14 has a second terminal and a control terminal connected to the first terminal and to the control terminal of the transistor N15, respectively. The control terminals of the transistors N14 and N15 are both driven by the first selection signal Vp. A second terminal of the transistor N15 (denoted as node D12) is connected to a second terminal of the transistor N16. The transistor N16 receives at its control terminal the second selection signal Vp1, whereas the first terminal of the transistor N16 is connected to the output terminal of the voltage switch 435.

Two n-channel MOSFETs N17 and N18 are connected in series between node D11 and the ground. In particular, the transistor N17 has a second terminal connected to node D11 the control terminal which receives the supply voltage Vdd, and a first terminal (denoted as node D13) connected to a second terminal of the transistor N18. The transistor N18 has a first terminal connected to ground and a control terminal adapted to receive the complemented signal Vp1#.

In the example at issue, the control signals PENABLE1, PENABLE2 and PENABLE3 are provided by a control circuit 460. In particular, the first control signal PENABLE1 is provided through an NAND gate 465 that receives the first selection signal Vp and the second selection signal Vp1. The second control signal PENABLE2 is provided through an EX-OR gate 470 that receives the first selection signal Vp and the second selection signal Vp1. The third control signal PENABLE3 is provided through a OR gate 475 that receives the first selection signal Vp and the second selection signal Vp1.

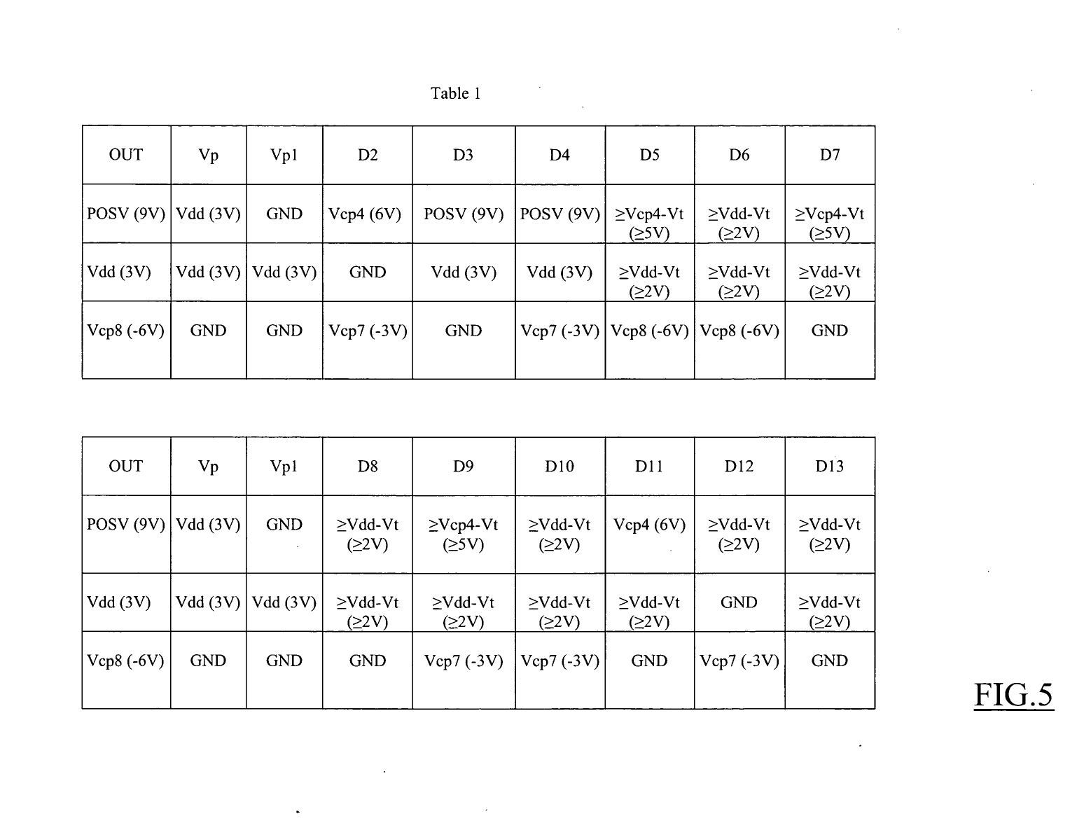

Referring now jointly to FIGS. 4 and 5, a Table 1 is shown in FIG. 5, reporting exemplary voltages of the most significant nodes of the single-word-line selector block 215 as a function of the operation to be performed on the memory device. In particular, according to the assertion state of the first selection signal Vp and the second selection signal Vp1, the word-line-selector block 215 brings the selecting signal OUT to the desired voltage during the operation to be performed; for example, during the programming operation; the selecting signal OUT reaches the programming voltage POSV for the selected word line WL and the supply voltage Vdd for the unselected word lines. Whereas, during the erasing operation the selecting signal OUT reaches the operative voltage Vcp8 (in the example at issue, Vcp8=−6V). During the program operation, for selecting the word line to the memory cell(s) to be programmed belong(s) the first selection signal Vp is asserted (at the supply voltage Vdd) and the second selection signal Vp1 is deasserted (at the reference voltage GND). In this condition, the control circuit 460 asserts the control signals PENABLE1, PENABLE2 and PENABLE3 (bringing them to the supply voltage Vdd).

The single-word-line selector block 215 associated with the selected word line operates as follows. Since the second control signal PENABLE2 is asserted, the first terminal of the transistor N13 receives the operative voltage Vcp4 (for example, Vcp4=6V). In this way, the transistor N13 is turned on (since its driving voltage is lower than its threshold voltage), and the node D11 thus reaches the fourth operative voltage Vcp4 (in the example at issue, approximately equal to 6V). The transistor N14 is turned on, as well (because its driving voltage is equal to the supply voltage Vdd), so the node D2 is brought to 6V. The transistor N18 is turned off (since its driving voltage is equal to zero), thus the transistor N17 cannot conduct any current; in this biasing condition, the voltage of the node D13 takes a value to not less than the supply voltage Vdd minus the threshold voltage of the transistor N17 (in the example at issue, 3V−1V=2V) and does not interfere with the voltage of the node D11.

The transistor N16 is turned off as well (since its driving voltage is equal to zero), so the transistor N15 also cannot conduct any current. In this way, the node D12 can reach the supply voltage Vdd minus the threshold voltage of the transistor N15 (for example, the voltage of the node D12 takes a value not less than 3V−1V=2V as shown in Table 1).

Moreover, since the first control signal PENABLE1 is also asserted, the first terminal of the transistor N1 receives the programming voltage POSV (for example, POSV=9V), while its control terminal receives the fourth operative voltage Vcp4. In such a way, the transistor N1 is turned on, and brings the node D3 to the programming voltage POSV. Also the transistor N2 is turned on (since it receives at its control terminal the fourth operative voltage Vcp4), so the node D4 is brought to the programming voltage POSV. In such biasing condition, the transistor N3 receives the supply voltage Vdd between the nodes D4 and D2, and thus turns on. In this way, the selecting signal OUT reaches the programming voltage POSV (which is equal to 9V, as shown in Table 1).

Since the control signal PENABLE3 is asserted, the transistor N6 has the first terminal and the control terminal both receiving the reference voltage GND. Moreover, the transistor N5 has the control terminal which receives the supply voltage Vdd. In this biasing condition, the transistor N6 is turned off (because its driving voltage is equal to zero), and then the transistors N5 and N4 cannot conduct any current. In particular, the nodes D5 and D6 reach the voltage of the control terminals of the transistors N4 and N5 minus the threshold voltage thereof, respectively (for example, the voltage of the node D6 takes a value not less than 3V−1V=2V and the voltage of the node D5 takes a value not less than 6V−1V=5V).

In the circuital structure 445, the transistor N9 is turned off (since its driving voltage is equal to zero). Thus, the transistors N7 and N8 cannot conduct any current, so the nodes D8 and D7 take a voltage value not less than to the voltage of their respective control terminals minus the threshold voltage (for example, the voltage of the node D8 falls to approximately 3V−1V=2V and the voltage of the node D7 falls to approximately 6V−1V=5V). Likewise, in the circuital structure 450 the transistor N12 is turned off (since its driving voltage is equal to zero) and the transistors N10 and N11 cannot conduct any current, so the nodes D9 and D10 take a voltage value approximately equal to the voltage of their control terminals minus the threshold voltage, respectively (for example, the voltage of the node D10 takes a voltage value of approximately 3V−1V=2V and the voltage of the node D9 takes a voltage value approximately equal to 6V−1V=5V). In such a way, the two circuital structures 445 and 450 do not interfere with the voltage of the nodes D3 and D4, respectively.

During the program operation of the memory cell(s) corresponding to the selected word line, each transistor of the single-word-line block 215 sustains (between its control terminal and any other terminal thereof) voltage differences at most equal to the supply voltage Vdd.

As above described, during this operation the branch including the transistors N4, N5 and N6 and the branch including the transistors N15 and N16 are not conductive paths so do not interfere with the voltage reached by the node D60 and D2, respectively. In this biasing condition, these branches are able to sustain a voltage drop equal to the programming voltage POSV and the operative voltage Vcp4, respectively, without breakdown of the low-voltage transistors thereof.

In an embodiment of the invention, both the programming voltage POSV and the operative voltage Vcp4 are an integer multiple of the supply voltage Vdd (in the example at issue, POSV=3Vdd and Vcp4=2Vdd). In order to maintain nonconductive the branch including the transistors N4, N5 and N6 and the branch including the transistors N15 and N16, each branch includes a number of low-voltage transistors connected in series equal to the integer multiple. In the example at issue, three low voltage transistors N4, N5 and N6 are provided in the branch adapted to sustain the programming voltage POSV=3Vdd and two transistors N15 and N16 are provided in the branch adapted to sustain the operative voltage Vcp4=2Vdd.

Similarly, the structures 445 and 450, when not forming conductive paths, are be able to sustain a voltage drop equal to the programming voltage POSV. For the same reason described above, the structures 445 and 450 includes a number of low-voltage transistors (in the example at issue, three corresponding low-voltage transistors) equal to the ratio between the programming voltage POSV and the supply voltage Vdd.

Concerning the unselected word lines, each word line selector block 215 receives the corresponding first selection signal Vp and the corresponding second selection signal Vp1 asserted (at the supply voltage Vdd). In this case, the selecting signal OUT is brought to the supply voltage Vdd. At same time, the control circuit 460 asserts the control signal PENABLE3 and deasserts the control signals PENABLE1 and PENABLE2.

The operation of the single word line selector block 215 associated with the generic unselected word line is as follows.

Since the third control signal PENABLE3 is asserted, the transistor N16 has the first terminal which receives the reference voltage GND and the control terminal which receives the supply voltage Vdd. In this way, the transistor N16 is turned on (since its driving voltage is higher than its threshold voltage), thus the node D12 reaches the reference voltage GND. The transistor N15 is as well turned on (because its driving voltage is equal to the supply voltage Vdd), thereby bringing the node D2 to the reference voltage GND.

Since the second control signal PENABLE2 is deasserted, the transistor N13 has the first terminal that receives the supply voltage Vdd, and is thus turned off (since its driving voltage is equal to zero). Thus the transistor N14 cannot conduct any current; in this biasing condition, the voltage of the second terminal of the transistor N14 does not interfere with the voltage of the node D11.

The node D11 takes a voltage value not less than approximately the supply voltage Vdd minus the threshold voltage of the transistor N14 (for example, the node voltage of the node DII can reach 3V−1V=2V).

Moreover, the transistor N18 is turned off (because its driving voltage is equal to zero), so the transistor N17 cannot conduct any current. Also in this case, the voltage of the second terminal of the transistor N18 (i.e., the node D13) takes a value not less than approximately the supply voltage Vdd minus the threshold voltage of the transistor N17 (in the example at issue, the voltage of the node D13 reaches at most 3V−1V=2V).

Since the first control signal PENABLE1 is deasserted, the control terminal of the transistor N1 receives the reference voltage GND, whereas the first terminal receives the supply voltage Vdd. In this biasing condition, the transistor N1 is turned on, so that the voltage of the node D3 reaches the supply voltage Vdd. Moreover, the transistor N2 is turned on (since it receives at its control terminal the reference voltage GND), so the node D4 is brought to the supply voltage Vdd. The transistor N3 receives the reference voltage GND at its control terminal, and is thus turned on. In such a way, the selecting signal OUT reaches the supply voltage Vdd.

Since the control signal PENABLE3 is asserted, the transistor N6 has the first terminal and the control terminal that receive the reference voltage GND. Moreover, the transistor N5 has the control terminal which receives the supply voltage Vdd. In this biasing condition, the transistor N6 is turned off (because its driving voltage is equal to zero) and then the transistors N5 and N4 cannot conduct any current. Thus, the nodes D5 and D6 reach the voltage of the control terminal of the transistor N5 minus its threshold voltage.

Regarding the circuital structures 445 and 450, the transistors N9 and N12 are turned off, so the two structures 450 and 445 cannot conduct any current, and do not interfere with the voltage reached by the nodes D3 and D4, respectively. As can be noted, during the program operation of the memory cell(s) each transistor of the single-word-line selector block 215 (which is coupled to a corresponding unselected word line) sustains (between its control terminal and any other terminal thereof) voltage differences at most equal to the supply voltage Vdd.

During an erasing operation, the selection signals Vp and Vp1 are deasserted (at the reference voltage GND). More in detail, the control circuit 460 asserts the control signal PENABLE1, and deasserts the control signals PENABLE2 and PENABLE3.

Since the control signal PENABLE2 is deasserted, the first terminal of the transistor N13 receives the supply voltage Vdd. Moreover, the transistors N18 and N17 receive at their control terminals the supply voltage Vdd, and are turned on. In such a way, the voltage of the node D11 reaches the reference voltage GND. In this biasing condition, the transistors N13 and N14 are turned off (since their driving voltages are higher than their corresponding threshold voltages). Since the third control signal PENABLE3 is deasserted, the first terminal of the transistor N16 receives the seventh operative voltage Vcp7 (for example, Vcp7=−3V). In this biasing condition, the transistor N16 is turned on, and brings the node D12 to −3V. The transistor N15 is turned on, as well (because its driving voltage is higher than its threshold voltage) so the node D2 reaches the operative voltage Vcp7.

The transistor N6 has the first terminal and the gate terminal that receive the eighth operative voltage Vcp8 (in the example at issue, Vcp8=−6V) and the seventh operative voltage Vcp7 (in the example at issue, Vcp7=−3V), respectively, and is thus turned on. In such a way, the node D6 reaches −6V. The transistor N5 is turned on, as well, and brings the node D5 to the operative voltage Vcp8 (i.e., −6V). In this biasing condition, the transistor N4 is turned on, and the selecting signal OUT reaches the operative voltage Vcp8.

The two circuital structures 445 and 450 bring the nodes D3 and D4 to the reference voltage GND and the seventh operative voltage Vcp7, respectively, so the transistors N1, N2 and N3 are turned off and do not interfere with the voltage of the selecting signal OUT (since they do not conduct any current).

In particular, in the circuital structure 445,. the transistor N9 is turned on, and brings the node D8 to the reference voltage GND. In such a way, the transistor N8 is turned on (since its driving voltage is equal to the supply voltage Vdd) and the voltage of the node D7 reaches the reference voltage GND. The transistor N7 is turned on as well, and brings the node D3 to the reference voltage GND. Similarly to the circuital structure 445, the circuital structure 450 forms a conductive path adapted to bring the node D4 to the seventh operative voltage Vcp7 (in the example at issue, to −3V). For this purpose, the first terminal of the transistor N12 receives the seventh operative voltage Vcp7, and the transistor N12 is turned on (in fact, the transistor N12 has the driving voltage equal to the supply voltage Vdd). The voltage of the node D10 can reach the operative voltage Vcp7, thereby the transistor N11 is turned on. In this way, the node D9 reaches the operative voltage Vcp7 as well, and turns the transistor N10 on, which brings the node D4 to the operative voltage Vcp7.

During the erasing operation of the memory cell(s) (which are coupled to the selected word lines of the sector), each transistor of the single-word-line selector block 215 sustains (between its control terminal and any other terminal thereof) voltage differences at most equal to the supply voltage Vdd. In other words, the single word line selector block 215 may be implemented with only low-voltage transistors.

As described above, during the erasing operation, the branch including the transistors N13 and N14 and the branch including the transistors N1, N2 and N3 are not conductive paths, and do not interfere with the voltage which is reached by the nodes D2 and D60, respectively. In this biasing condition, the branch including the transistors N13 and N14 sustains a voltage drop equal to the difference between the supply voltage Vdd and the operative voltage Vcp7 (in the example at issue, 3V−(−3V)=6V=2Vdd) without breakdown of the low-voltage transistors. The branch including the transistors N1, N2 and N3 sustains a voltage drop equal to the difference between the supply voltage Vdd and the operative voltage Vcp8 (in the example at issue, equal to 3V−(−6V)=9V=3Vdd). Also in this case each branch includes a number of transistors equal to the voltage drop to be sustained divided by the supply voltage Vdd, in order to avoid undesired breakdown of low-voltage transistors thereof.

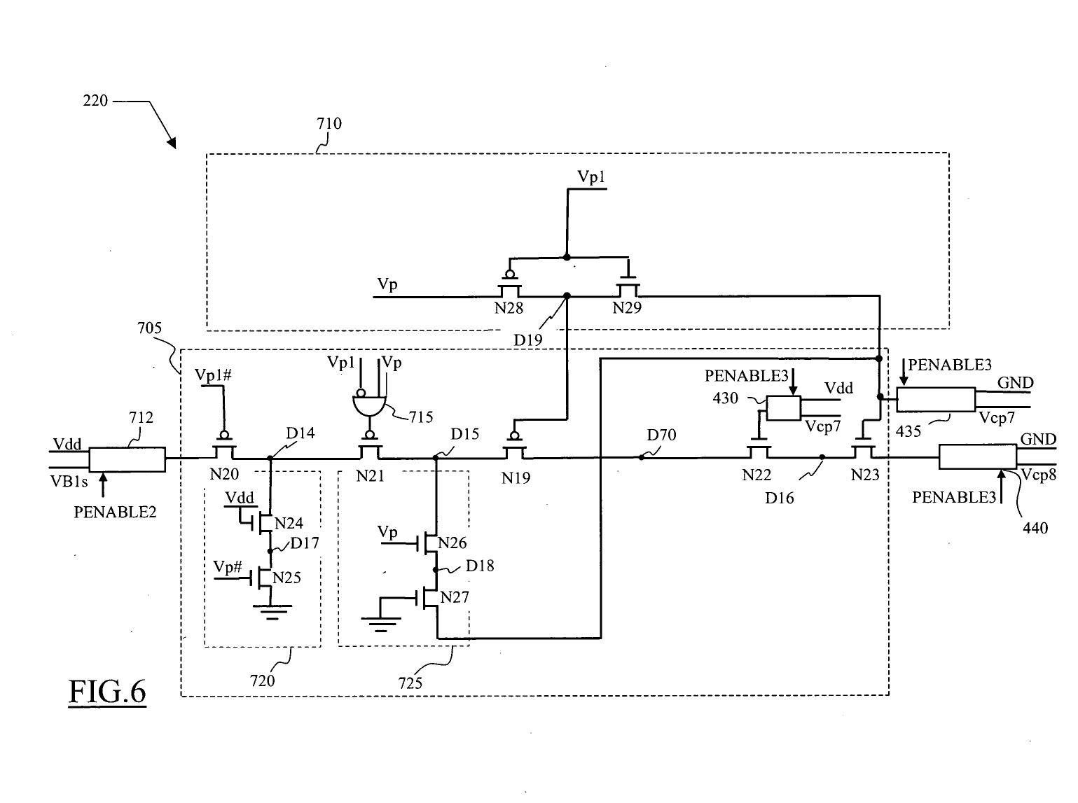

Moving to FIG. 6, an exemplary implementation of a generic first biasing block 220 is schematically shown. The first biasing block 220 includes a first circuital block 705 and a second circuital block 710.

The first circuital block 705 includes a first circuit branch with three p-channel MOSFETs N19, N20 and N21 connected in series, and a second circuit branch with two further series-connected n-channel MOSFETs N22 and N23, the first and second circuit branches being both connected to a common node D70. In particular, the transistor N20 has a control terminal which is adapted to receive the complemented first selection signal Vp1 and a first terminal which is connected to the output terminal of an eleventh voltage switch 712. The voltage switch 712 has two input terminals, respectively adapted to receive the first biasing voltage VB1s=6V and the supply voltage Vdd. The voltage switch 712 is controlled by the second control signal PENABLE2, and, according to the assertion state thereof, one of the switch input terminals is connected to the switch output terminal, so that the first terminal of the transistor N20 can be alternatively biased at the first biasing voltage VB1s or at the supply voltage Vdd.

A second terminal (denoted as node D14) of the transistor N20 is connected to a first terminal of the transistor N21, which has a control terminal connected to an output terminal of a two-input AND gate 715. The AND gate 715 receives the first selection signal Vp and the complemented second selection signal Vp1. The transistor N21 has a second terminal (denoted as node D15) connected to a first terminal of the transistor N19.

The second terminal (corresponding to the node D70) of the transistor N19 is connected to a second terminal of the transistor N22 and provides the first control signal VB1.

A first terminal of the transistor N22 (denoted as node D16) is connected to a second terminal of the transistor N23 which has its control and first terminals coupled to the voltage switches 435 and 440, respectively. Moreover, the control terminal of the transistor N22 is connected to a switch output terminal of the voltage switch 430.

The first circuital block 705 further includes two circuital structures 720 and 725.

In detail, the circuital structure 720 includes two n-channel MOSFETs N24 and N25 which are connected in series. In particular, the transistor N24 has a second terminal connected to a second terminal of the transistor N20 and a first terminal (denoted as node D17) connected to a second terminal of the transistor N25. The transistor N24 has a control terminal which receives the supply voltage Vdd. The transistor N25 has a first terminal which is adapted to remain at ground whereas at its control terminal it receives the complemented first selection signal Vp#.

The circuital structure 725 includes two series-connected n-channel MOSFETs N26 and N27. In particular, the transistor N26 has a second terminal connected to the node D15 and a first terminal (denoted as node D18) connected to a second terminal of the transistor N27. The transistor N26 has a control terminal which is adapted to receive the first selection signal Vp. The transistor N27 has a first terminal which is connected to the output terminal of the fifth voltage switch 435 and a control terminal which receives the reference voltage GND.

The second circuital block 710 includes a first circuit branch with one p-channel MOSFET N28, and a second circuit branch with one further n-channel MOSFET N29, the first and second circuit branches being both connected to a common node D19. In particular, the transistor N28 has a first terminal which is adapted to receive the first selection signal Vp and a second terminal which is connected to a second terminal (i.e., the node D19) of the transistor N29. Moreover, a control terminal of the transistor N28 is connected to a control terminal of the transistor N29 and receives the second selection signal Vp1. A first terminal of the transistor N29 is connected to the output terminal of the voltage switch 435.

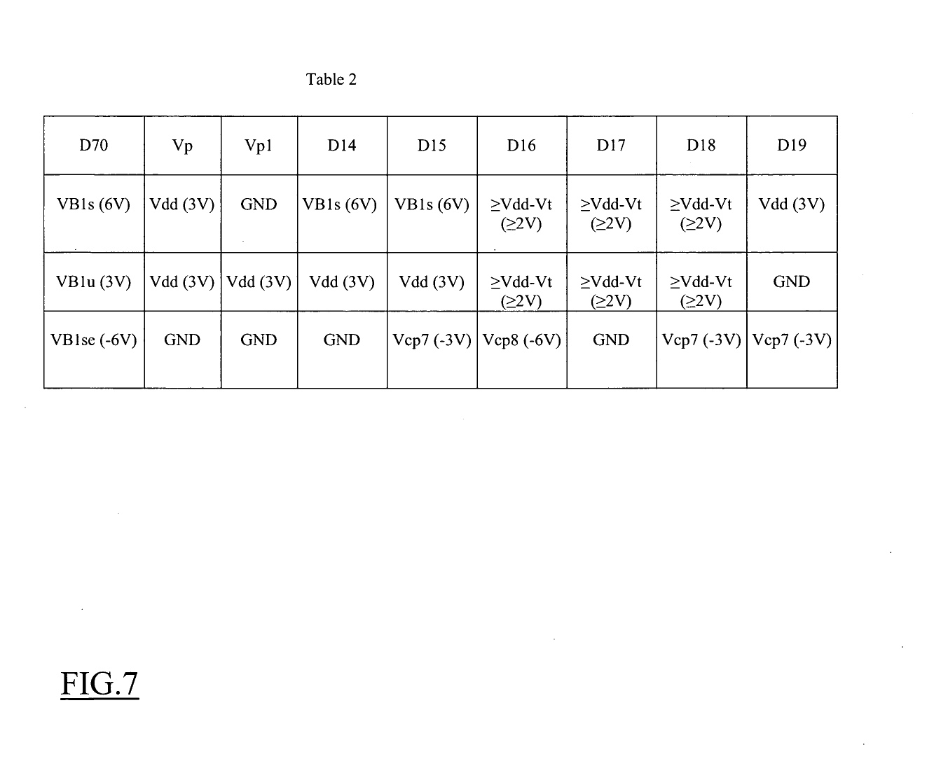

Referring now to FIG. 7 in combination with FIG. 6, a Table 2 is shown, illustrating the voltages of the nodes of the first biasing block 220 according to the operation to be performed on the memory device 100. In particular, according to the assertion state of the selection signals Vp and Vp1, the first biasing block 220 provides the first control signal VB1.

During a program operation, the selection signal Vp is asserted (at the supply voltage Vdd); when the selection signal Vp1 is de-asserted (at the reference voltage GND), the corresponding word line is selected for the program operation of the memory cell coupled thereto. More in detail, the control circuit 460 (FIG. 4) asserts the control signals PENABLE2 and PENABLE3 and causes the node D70 to reach the first control voltage VB1s (for example, VB1s=6V). In other words, by means a proper biasing of the first biasing block 220, the node D70 can reach the first control voltage VB1s (for example, VB1s=6V). In fact, as described above referring to FIG. 3A, during a program operation, for selecting the word line to which the memory cell(s) to be programmed belong(s), the first biasing block 220s provides the first control signal VB1 at the voltage VB1s.

The first biasing block 220 operates as follows.

The transistor N28 is turned on (because its driving voltage is equal to the supply voltage Vdd) and causes the node D19 to reach the supply voltage Vdd.

Since the third control signal PENABLE3 is asserted, the first terminal of the transistor N29 receives the reference voltage GND. In such a way, the transistor N29 is turned off (since its driving voltage is equal to zero).

Moreover, since the second control signal PENABLE2 is asserted, the first terminal of the transistor N20 receives the voltage VB1s (for example, VB1s=6V) and is turned on (since its driving voltage is equal to the supply voltage Vdd). In such a way, the voltage of the node D14 reaches 6V. Moreover, when the second control signal PENABLE2 is asserted, the control terminal of the transistor N21 receives the supply voltage Vdd, which turns on the transistor N21, bringing the node D15 to the voltage VB1s. In this biasing condition, the transistor N19 is turned on, so the node D70 can reach the first control voltage VB1s.

Since the third control signal PENABLE3 is asserted, the control and first terminals of the transistor N23 receive the reference voltage GND, and the transistor is turned off. Thus, the transistor N22 cannot conduct any current, and the voltage value at the node D16 remains at approximately the supply voltage Vdd minus the threshold voltage of the transistor N22.

During the program operation, the two structures 720 and 725 do not form conductive paths, so they do not interfere with the voltages of the nodes D14 and D15, respectively. In detail, in the structure 720 the transistor N25 is turned off (because its driving voltage is equal to zero). Thus, the transistor N24 cannot conduct any current and the voltage at the node D17 remains approximately at the supply voltage Vdd minus the threshold voltage of the transistor N24. Likewise, in the structure 725 the transistor N27 is turned off, and the node D18 remains at the supply voltage Vdd (which is the voltage of the control terminal of the transistor N26) minus the threshold voltage of the transistor N26.

During the program operation of the memory cell(s) corresponding to the selected word line, each transistor of the first biasing block 220 sustains across its control and first/second terminals at most the supply voltage Vdd.

Moreover, the circuital branch including the transistors N22 and N23 and the circuital branch including the transistor N29 respectively have a number of low-voltage transistors equal to the ratio between the voltage drop to be sustained when each branch is not conductive divided by the supply voltage Vdd.

Similarly, the circuital structures 720 and 725 have a number of low-voltage transistors equal to the ratio between the voltage drop to be sustained when each circuital structure is not conductive divided by the supply voltage Vdd (in the example at issue, the pairs of transistors N24-N25 and N26-N27, respectively).

Concerning the unselected word lines, each first biasing block 220 receives the corresponding first selection signal Vp and the corresponding second selection signal Vp1 asserted (at the supply voltage Vdd). In this case, the voltage of the node D70 reaches the first control voltage VB1u (for example, VB1u=3V). In other words, as described above referring to FIG. 4, during a program operation the first biasing block 220u provides the first control signal VBI at the voltage VB1u. In particular, according to the assertion state of the first and second selecting signals Vp and Vp1, the control circuit 460 de-asserts the second control signal PENABLE2 (at the reference voltage GND) and asserts the third control signal PENABLE3 (at the supply voltage Vdd).

Since the second control signal PENABLE2 is deasserted, the first terminal of the transistor N20 receives the supply voltage Vdd. The control terminal of the transistor N21 receives the reference voltage GND. Moreover, since the third control signal PENABLE3 is asserted, the first terminal and the control terminal of the transistor N23 receive the reference voltage GND, whereas the control terminal of the transistor N22 receives the supply voltage Vdd.

When the third control signal PENABLE3 is asserted, the transistor N29 has the first terminal receiving the reference voltage GND. In this biasing condition, the transistor N29 is turned on (since its driving voltage is equal to the supply voltage Vdd) and causes the node D19 to reach the reference voltage GND.

Moreover, the driving voltage of the transistor N28 is equal to zero, and the transistor is turned off.

The transistor N20 is turned on (since its driving voltage is equal to the supply voltage Vdd), thereby bringing the node D14 to the supply voltage Vdd. In this biasing condition, the transistor N21 is turned on and causes the node D15 to reach the supply voltage Vdd. The transistor N19 is thus turned on, so the voltage of the node D70 reaches the supply voltage Vdd. In other words, the first control signal VBI reaches the voltage Vdd (in the example at issue, VB1u=Vdd=3V).

The transistor N23 is turned off (because its driving voltage is equal to zero) and thus transistor N22 cannot conduct any current. In such a way, the voltage of the node D16 takes a value not less than the supply voltage Vdd (i.e., the voltage of the control terminal of the transistor N22) minus the threshold voltage of the transistor N22.

Also in this case, the circuital structures 720 and 725 do not form conductive paths, so they do not interfere with the voltages of the nodes D14 and D15, respectively. Moreover, the nodes D17 and D18 reach the same voltages (as shown in Table 2) of the preceding case in which the first biasing block 220 biases the selected word line.

During an erase operation, the first and second selection signals Vp and Vp1 are deasserted (at the reference voltage GND). More in detail, the control circuit 460 deasserts the control signals PENABLE2 and PENABLE3, thereby allowing to select each word line of the sector 105.

Since the control signal PENABLE2 is deasserted, the first terminal of the transistor N20 receives the supply voltage Vdd. The control terminal of the transistor N21 receives the reference voltage GND.

Moreover, since the third control signal PENABLE3 is deasserted, the transistor N23 has the first terminal and the control terminal which receive the operative voltages Vcp7 and Vcp8, respectively. In the example at issue, Vcp7=−3V and Vcp8=−6V. The transistor N22 has the control terminal which receives the operative voltage Vcp7.

In this biasing condition, the transistor N29 is turned on (since its first terminal receives −3V) thus causing the node D19 to reach the operative voltage Vcp7 (in the example at issue, −3V). In such a way, the transistor N28 is turned off.

The transistor N23 is turned on (because its driving voltage is equal to the supply voltage Vdd) and causes the node D16 to reach the operative voltage Vcp8 (in the example at issue, −6V). In such a way, the transistor N22 is turned on and brings the node D70 to the operative voltage Vcp8. In other words, the voltage of the node D70 (i.e., the voltage VB1se) is equal to the operative voltage Vcp8.

During the erase operation the circuital structures 720 and 725 forms conductive paths adapted to bring the nodes D14 and D15 to the reference voltage GND and to the operative voltage Vcp7, respectively.

In particular, in the circuital structure 720 the transistor N25 is turned on (since its driving voltage is equal to the supply voltage Vdd) and causes the node D17 to reach the reference voltage GND. The transistor N24 is turned on as well, and causes the node D14 to reach the reference voltage GND.

Likewise, in the circuital structure 725, the transistor N27 is turned on so that the node D18 can reach the operative voltage Vcp7 (in the example at issue, −3V). In such a way, the transistor N26 is turned on and brings the node D15 to the operative voltage Vcp7.

In such a way, the transistor N19 is turned off and does not interfere with the voltage of the node D70.

During the erasing operation of the memory cell(s) (coupled to the selected word lines), each transistor of the first biasing block 220 sustains across its control and first/second terminals at most the supply voltage Vdd. In other words, the first biasing block 220 can be implemented with only low-voltage transistors.

Moreover, the circuital branch including the transistors N19, N20 and N21 and the circuital branch including the transistor N28 respectively have a number of low voltage transistors equal to the ratio between the voltage drop to be sustained when each branch is not conductive divided by the supply voltage Vdd.

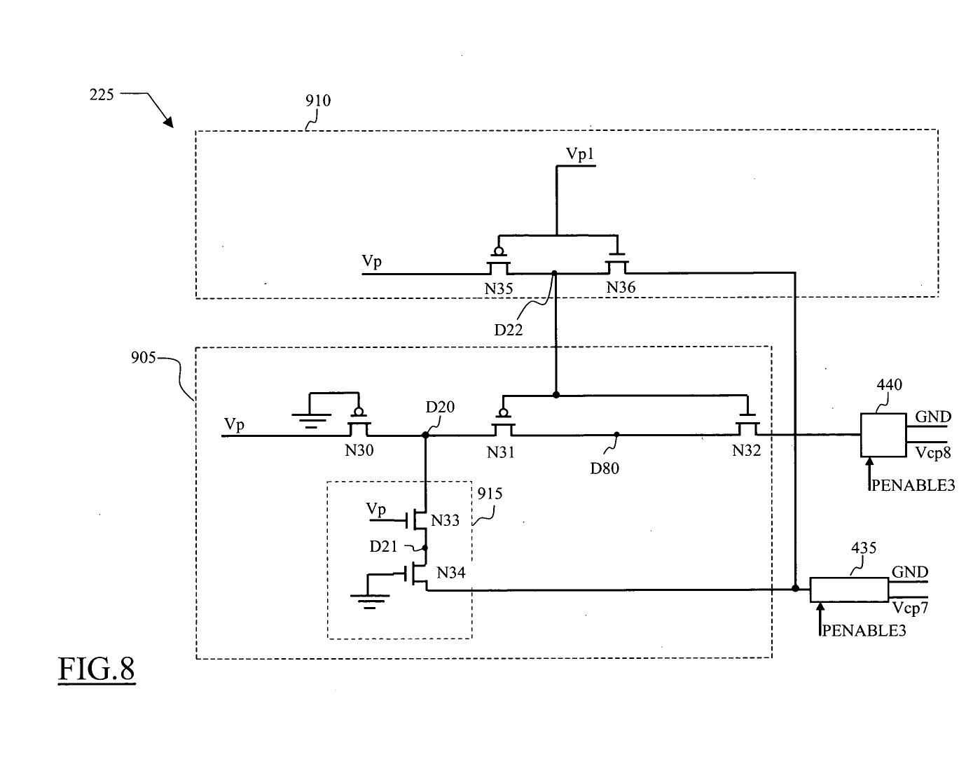

Referring to FIG. 8, an exemplary implementation of a generic second biasing block 225 is schematically shown. The second biasing block 225 includes a first circuital block 905 and a second circuital block 910.

The first circuital block 905 includes a first circuit branch with one n-channel MOSFET N32, and a second circuit branch with two series-connected p-channel MOSFETs N30 and N31, the first and second circuit branches being both connected to a common node D80.

In particular, the transistor N30 has a control terminal adapted to receive the reference voltage GND and a first terminal receiving the first selection signal Vp. A second terminal (denoted as node D20) of the transistor N30 is connected to a first terminal of the transistor N31 which has a control terminal connected to a control terminal of the transistor N32.

A second terminal of the transistor N31 (corresponding to the node D80) which, during the operation of the second biasing block 225, provides the second control signal VB2, is connected to a second terminal of the transistor N32. The voltage switch 440 selectively connects one of its two input terminals to a first terminal of the transistor N32 according to the operation to be performed on the memory device.

The first circuital block 905 further includes a circuital structure 915. In detail, the circuital structure 915 includes two n-channel MOSFETs N33 and N34 which are connected in series. In particular, the transistor N33 has a second terminal connected to the second terminal of the transistor N30 and a first terminal (denoted as node D21) connected to a second terminal of the transistor N34. The transistor N34 has a control terminal which receives the reference voltage GND and a first terminal coupled to the output of the voltage switch 435.

The second circuital block 910 includes a p-channel MOSFET N35 connected in series to a n-channel MOSFET N36. In particular, the second circuital block 910 has a same circuital structure as the second circuital block 710 (in an alternative embodiment of the invention, the second biasing block 225 may have the first circuital block 905 directly connected to the node D19 of second circuital block 710 of the first biasing block 220 instead of to the node D22 as shown in FIG. 8). In detail, the transistor N35 has a second terminal which is connected to a second terminal (denoted as node D22) of the transistor N36 and also connected to the control terminals of the transistors N31 and N32.

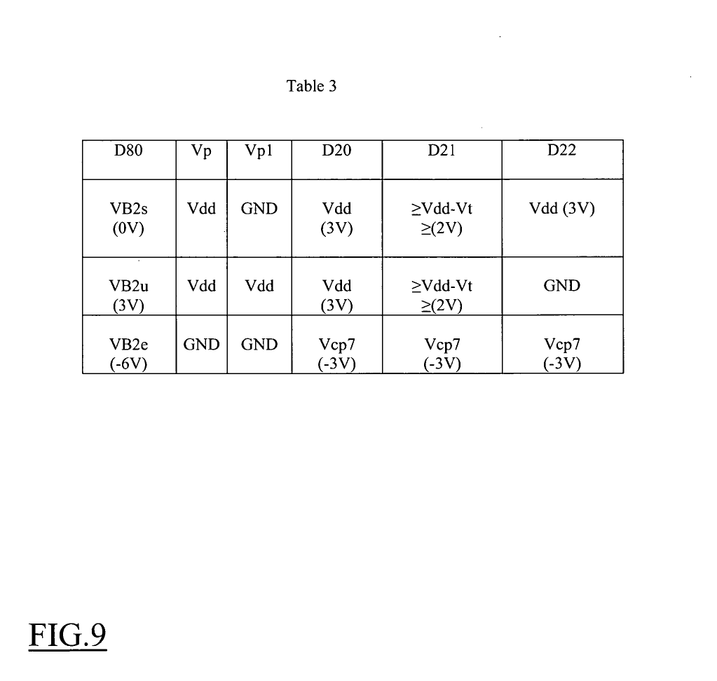

Referring now jointly to FIGS. 8 and 9, a Table 3 is shown in FIG. 9, reporting exemplary voltages of significant nodes of the second biasing block 225 depending on the operation to be performed on the memory device.

In particular, according to the assertion state of the first and second selection signals Vp and Vp1, the second biasing block 225 provides the second control signal VB2 on the node D80.

During a program operation, the selection signal Vp is asserted (at the supply voltage Vdd); when the selection signal Vp1 is de-asserted (at the reference voltage GND), the corresponding word line is selected for the program operation of the memory cell(s) coupled thereto. More in detail, the control circuit 460 asserts the control signals PENABLE2 and PENABLE3 and causes the node D80 to reach the voltage VB2s (for example, VB2s=0V). In other words, by means a proper biasing of the first biasing block 225, the node D80 can reach the voltage VB2s. In fact, as described above referring to FIG. 4, during a program operation, for selecting the word line to which the memory cell(s) to be programmed belong(s), the first biasing block 225s provides the second control signal VB2 at the voltage VB2s.

In this biasing condition, as described above referring to the second circuital block 710 (FIG. 6), the node D22 of the second circuital block 910 reaches the supply voltage Vdd. Moreover, since the third control signal PENABLE3 is asserted, the transistor N32 has the first terminal which receives the reference voltage GND by the voltage switch 440.

The transistor N32 is thus turned on (because its driving voltage is higher than its threshold voltage) and causes the node D80 to reach the reference voltage GND (corresponding to the desired voltage for the second control signal VB2).

The transistor N30 is turned on (since its driving voltage is equal to the supply voltage Vdd) and brings the node D20 to the supply voltage Vdd. In such a way the transistor N31 is turned off.

In this biasing condition, the circuital structure 915 forms a nonconductive path. In detail, the transistor N34 has the first terminal which receives the reference voltage GND and is thus turned off. The transistor N33 (being connected in series to the transistor N34) cannot conduct any current. Thus, the voltage of the node D21 takes a value not less than the supply voltage Vdd minus the threshold voltage of the transistor N33 (for example, as shown in Table 3, the voltage of the node D21 reaches at most 3V−1V=2V).

Concerning the unselected word lines, each second biasing block 225 receives the corresponding first selection signal Vp and the corresponding second selection signal Vp1 asserted (at the supply voltage Vdd). In this case, the voltage of the node D80 reaches the voltage VB2u (for example, VB2u=3V). In other words, as described above referring to FIG. 4, during a program operation the second biasing block 225u corresponding to the unselected word line provides the second control signal VB2 at the voltage VB2u.

The control circuit 460 (FIG. 4) asserts the control signal PENABLE3 and deasserts the control signal PENABLE2. The operation of the second biasing block 225u associated with the generic unselected word line is as follows.

As described above referring to the second circuital block 710, the node D22 of the second circuital block 910 reaches the reference voltage GND, which is fed to the control terminals of the transistors N31 and N32. Moreover, since the third control signal PENABLE3 is asserted, the transistors N32 and N34 have the corresponding first terminal which receives the reference voltage GND.

The transistor N30 is turned on (because its driving voltage is higher than its threshold voltage) and causes the node D20 to reach the supply voltage Vdd. The transistor N31 is turned on, so that the voltage of the node D80 reaches the supply voltage Vdd (i.e., VB2u=3V). In such a way, the transistor N32 is turned off.

Also in this case, the circuital structure 915 forms a nonconductive path, and the voltage of the node D21 reaches a value to not less than the supply voltage Vdd minus the threshold voltage of the transistor N33.

During the programming operation of the memory cell(s), each transistor of the second biasing block 225 sustains across its control and first/second terminals at most the supply voltage Vdd.

Moreover, the circuital branch including the transistor N32 has only one low voltage transistor, since the ratio between the voltage drop to be sustained when said branch is not conductive divided by the supply voltage Vdd is equal to one.

Similarly, the circuital structure 915 has a number of low-voltage transistors equal to the ratio between the voltage drop to be sustained when said circuital structure is not conductive divided by supply voltage Vdd (in the example at issue, the pair of transistors N33-N34).

During an erase operation, the first and second selection signals Vp and Vp1 are deasserted (at the reference voltage GND). In more detail, the control circuit 460 (FIG. 4) deasserts the control signals PENABLE2 and PENABLE3 thereby allowing the selection of all the word lines of the sector to be erased.

Since the control signal PENABLE3 is deasserted, the transistors N32 and N34 have the corresponding first terminal which receives the operative voltages Vcp8 and Vcp7, respectively. In the example at issue, Vcp7=−3V and Vcp8=−6V. Moreover, the transistors N32 and N31 have the control terminal which receives the operative voltage Vcp7.

In this biasing condition, the transistor N32 is turned on and causes the node D80 to reach the operative voltage Vcp8. In the example at issue, Vcp8=−6V (i.e., VB2se=−6V).

During the erase operation the circuital structure 915 forms a conductive path adapted to bring the node D20 to the operative voltage Vcp7. In particular, in the circuital structure 915 the transistor N34 is turned on (since its driving voltage is equal to the supply voltage Vdd) and causes the node D21 to reach the operative voltage Vcp7. In this biasing condition, the transistor N33 is turned on so that the node D20 can reach the operative voltage Vcp7.

In such a way, the transistors N30 and N31 are turned off, and do not interfere with the voltage (i.e., VB2se=−6V) of the node D80.

During the operation of the second biasing block 225, each transistor thereof sustains (between its control terminal and any other terminal thereof) voltage differences at most equal to the supply voltage Vdd. Thus, the second biasing block 225 can be implemented with only low-voltage transistors.

Also in this case, the circuital branch including the transistors N30 and N31 includes a number of low-voltage transistors equal to the ratio between the voltage drop to be sustained when said branch is not conductive and the supply voltage Vdd.

According to an embodiment of the present invention, the possibility of using only low-voltage transistors for implementing the row selector of a memory device is contemplated, even in the case the voltage values to be handled are higher (in absolute value) than the supply voltage Vdd, or lower than the reference voltage GND. As described above, a low voltage transistor is a device designed in such a way to guarantee the capability of sustaining, at least between a pair of its terminals, and particularly at least between the control terminal and another one of its terminals, voltage differences up to the supply voltage Vdd.

The possibility of including only low-voltage devices in the row selector may allow significant simplification of the manufacturing process of the memory device.

An embodiment of the present invention provides a row selector, which, by adopting a particular circuital topology, avoids the use of HV transistors. More in particular, according to an embodiment of the present invention, such a result is achieved by providing, in some circuital structures of the row selector, a number of series-connected LV transistors equal to the ratio of the voltage drop (in absolute value) that the generic circuital structure has to withstand when it is not conductive, to the maximum voltage difference that a single LV transistor can sustain across its terminals, particularly across its control and source/gate or bulk terminal (i.e., Vdd=3 Volts in case of LV transistors).

In other words, the number of low-voltage transistors connected in series in order to form the circuital structures of the row selector depends on the maximum voltage drop that each circuital structure is able to sustain when it forms a nonconductive path.

For example, the circuital structure 235u (FIG. 3A) of the intermediate circuit 210 when forming a nonconductive path sustains a maximum voltage drop equal to the programming voltage POSV. In an embodiment of the invention, the programming voltage POSV is equal to an integer multiple of the supply voltage Vdd (for example POSV=3Vdd), so that the circuital structures 235u can be implemented with a number of low voltage transistors equal to the integer multiple (in the example at issue, the three transistors M4u, M5u and M6u).

Naturally, in order to satisfy local and specific requirements, a person skilled in the art may apply to the solution described above many modifications and alterations. Particularly, although one or more embodiments of the present invention have been described with a certain degree of particularity, it should be understood that various omissions, substitutions and changes in the form and details as well as other embodiments are possible; moreover, it is expressly intended that specific elements and/or method steps described in connection with any disclosed embodiment of the invention may be incorporated in any other embodiment as a general matter of design choice.

It should be apparent that the numerical examples of the different voltages described above are merely illustrative and are not to be interpreted in a limitative manner.

In any case, the use of other types of transistors, (for example, bipolar junction transistors) is within the scope of the invention.

Similar considerations apply if the memory device has a different structure or includes equivalent components.

Likewise, it is possible to use the proposed solution for biasing the selected bit lines during the operations performed on the memory device.

An electronic system, such as a computer system, may incorporate the memory device 100 of FIG. 1, and may include another circuit, such as a controller, coupled to the memory device. Such a system may be implemented on one or more integrated circuits (ICs).

1. A row selector for a semiconductor memory including a plurality of memory cells coupled to a corresponding plurality of word lines, the row selector comprising, for each word line:
a first biasing circuit path adapted to bias the corresponding word line to a programming voltage when said corresponding word line is selected for selectively performing a program operation on at least one memory cell coupled to the corresponding word line, the first biasing circuit path comprising programming voltage provisioning means adapted to provide the programming voltage;
a second biasing circuit path which is adapted to receive, from program-inhibit voltage provisioning means, a program inhibit voltage, and to provide to the corresponding word line said program inhibit voltage when the word line is unselected during the program operation;
first biasing means for driving the second biasing circuit path in order to control a conduction state thereof;
wherein:
said first biasing circuit path includes a first transistor controlled to be electrically conductive when the corresponding word line is selected, and to be electrically non-conductive when the corresponding word line is unselected;
said first biasing means controls the second biasing circuit path to be conductive when, during the program operation, the corresponding word line is unselected, and
said second biasing circuit path includes a plurality of series-connected transistors, a number of transistors in said plurality being at least equal to the smallest integer not less than an absolute value of a ratio between a voltage equal to the difference between the programming voltage and the program-inhibit voltage to a predetermined maximum voltage.

2. The row selector according to claim 1, wherein the second biasing circuit path is adapted to receive from erase-voltage provisioning means an erasing voltage and to provide to the corresponding word line said erasing voltage during an erase operation performed on at the least two word lines of said plurality, said first biasing means controlling the second biasing circuit path so as to be conductive when performing the erase operation.

3. The row selector according to claim 1, wherein each transistor of said plurality is adapted to guarantee the capability of sustaining voltage differences across at least a control terminal and another terminal thereof up to an absolute value of a supply voltage of the semiconductor memory.

4. The row selector according to claim 2, wherein said plurality of transistors includes a second transistor controlled by said first biasing means to be conductive during the erase operation and when the corresponding word line is unselected.

5. The row selector according to claim 2, wherein the first transistor is adapted to guarantee the capability of sustaining, at least across a control terminal and another terminal thereof, voltage differences up to the absolute value of the supply voltage.

6. The row selector according to claim 2, wherein the first biasing circuit path is further adapted to bias the corresponding word line to a reading voltage when said corresponding word line is selected for selectively performing a read operation on at least one memory cell coupled to the corresponding word line, the first biasing circuit path comprising reading voltage provisioning means adapted to provide the reading voltage.

7. The row selector of claim 6, wherein the first biasing circuit path further includes a third transistor adapted to convey the programming voltage from said programming voltage provisioning means when said corresponding word line is selected for selectively performing the program operation, and to convey the reading voltage from said reading voltage provisioning means when said corresponding word line is selected for selectively performing the reading operation, said third transistor being adapted to guarantee the capability of sustaining at least across a control terminal and another terminal thereof voltage differences up to the absolute value of the supply voltage of the semiconductor memory.

8. The row selector according to claim 6, further including second biasing means for controlling the third transistor in such a way as to be conductive when the corresponding word line is selected for selectively performing the program operation or alternatively for selectively performing the read operation, and for controlling the third transistor to be nonconductive during the erase operation.

9. The row selector according to claim 8, wherein the first circuit path includes a fourth transistor coupling the second biasing means to a control terminal of the third transistor, the fourth transistor being adapted to guarantee the capability of sustaining, at least across a control terminal and another terminal thereof, voltage differences up to the absolute value of the supply voltage.

10. The row selector according to claim 9, wherein the first biasing means include a first biasing block which is adapted to provide a first control signal controlling the first transistor, said first control signal being at a first selecting control voltage adapted to cause the first transistor to be conductive when the corresponding word line is selected for selectively performing the program operation, said first control signal being at a first unselecting control voltage when the corresponding word line is unselected during the program operation and at a first erasing control voltage during the erase operation, the first unselecting control voltage and the first erasing control voltage being adapted to cause the first transistor to be nonconductive.

11. The row selector according to claim 9, wherein the first biasing means include a second biasing block which is adapted to provide a second control signal controlling the second transistor, said second control signal being at a second selecting control voltage adapted to cause the second transistor to be not conductive when the corresponding word line is selected for selectively performing the program operation, said second control signal being at a second unselecting control voltage when the corresponding word line is unselected during the program operation and at a second erasing control voltage during the erase operation, the second unselecting control voltage and the second erasing control voltage being adapted to cause the second transistor to be conductive.

12. The row selector according to claim 11, wherein at least one of the programming voltage provisioning means, the first biasing block and the second biasing block includes a corresponding first circuit branch and second circuit branch which are connected to a corresponding output circuit node, the first circuit branch and the second circuit branch being adapted to receive at a corresponding input terminal thereof a corresponding first and second operative input signal, said output circuit node being adapted to provide a corresponding output signal depending on the first or second operative input signals, the first circuit branch and the second circuit branch including a corresponding first and second plurality of series-connected transistors, a corresponding number of transistors in said first plurality being at least equal to the smallest integer not less than an absolute value of a ratio between a first drop voltage across the first circuit branch when said first circuit branch is not conductive and the predetermined maximum voltage, a corresponding number of transistors in said second plurality being at least equal to the smallest integer not less than an absolute value of a ratio between a second drop voltage across the second circuit branch when said second circuit branch is not conductive and the predetermined maximum voltage.

13. The row selector according to claim 6, wherein said programming voltage is a first multiple of the supply voltage, said reading voltage is a second multiple of the supply voltage, said erasing voltage is a third multiple of the supply voltage, the programming voltage and the reading voltage having a first sign, the erasing voltage having a second sign, the second sign being opposite to the first sign, at least one of the first multiple, the second multiple, and the third multiple being higher in absolute value than the supply voltage.

14. The row selector according to claim 9, wherein the first, second, third, fourth transistors comprise MOSFETs.

15. A memory-line driver, comprising:
an output node operable to be coupled to a memory line;
a programming path operable to couple a programming voltage to the output node during a programming cycle; and
an erasing path including a first supply node, operable to couple an erasing voltage from the supply node to the output node during an erasing cycle, and operable to receive a first reference voltage on the supply node and to electrically isolate the output node from the supply node during the programming cycle, the erasing path further including a number of transistors serially coupled between the output and supply nodes, each transistor having a breakdown voltage that is no less than a pre-established breakdown voltage, the number of transistors being greater than or equal to a ratio of the difference between the programming and reference voltages to the pre-established breakdown voltage.

16. The memory-line driver of claim 15, further comprising:
each of the transistors comprises a control node and two conduction nodes; and
a bias circuit operable to generate a respective bias signal on the control node of each transistor such that no voltage across the control node and any one of the conduction nodes exceeds the pre-established breakdown voltage during the programming cycle.

17. The memory-line driver of claim 15, further comprising:
each of the transistors comprises a control node and two conduction nodes; and
a bias circuit operable to generate a respective bias signal on the control node of each transistor such that no voltage across the control node and any one of the conduction nodes exceeds the pre-established breakdown voltage during the erasing cycle.

18. The memory-line driver of claim 15 wherein:
the programming path is operable to couple the programming voltage to the output node during a programming cycle in which the memory line is selected; and
the erase path is operable to couple the first reference voltage from the supply node to the output node during a programming cycle in which the memory line is unselected.

19. The memory-line driver of claim 15, further comprising:
each of the transistors comprises a control node and two conduction nodes; and
a bias circuit operable to generate a respective bias signal on the control node of each transistor such that no voltage across any two of the control node and conduction nodes exceeds the pre-established breakdown voltage during the programming cycle.

20. The memory-line driver of claim 15, further comprising:
each of the transistors comprises a control node and two conduction nodes; and
a bias circuit operable to generate a respective bias signal on the control node of each transistor such that no voltage across any two of the control node and conduction nodes exceeds the pre-established breakdown voltage during the erasing cycle.

21. A memory, comprising:
a memory cell;
a memory line coupled to the memory cell; and
a line driver coupled to the memory line and including
a programming path operable to couple a programming voltage to the memory line during a programming cycle, and
an erasing path including a first supply node, operable to couple an erasing voltage from the supply node to the memory line during an erasing cycle, and operable to receive a first reference voltage on the supply node and to electrically isolate the memory line from the supply node during the programming cycle, the erasing path further including a number of transistors serially coupled between the memory line and the supply node, each transistor having a breakdown voltage that is no less than a pre-established breakdown voltage, the number of transistors being greater than or equal to a ratio of the difference between the programming and reference voltages to the pre-established breakdown voltage.

22. The memory of claim 21 wherein the memory cell comprises a nonvolatile memory cell.

23. The memory of claim 21 wherein the memory line comprises a row line.

24. The memory of claim 21, further comprising:
an address bus operable to receive an address of the memory cell;
an address decoder coupled to the address bus and to the line driver and operable to generate a select signal in response to the address; and
wherein the programming path is operable to couple the programming voltage to the memory line in response to the select signal; and
the erasing path is operable to electrically isolate the memory line from the supply node in response to the select signal.

25. A system, comprising:
a controller; and
a memory coupled to the controller and comprising,
a memory cell,
a memory line coupled to the memory cell, and
a line driver coupled to the memory line and including
a programming path operable to couple a programming voltage to the memory line during a programming cycle, and
an erasing path including a first supply node, operable to couple an erasing voltage from the supply node to the memory line during an erasing cycle, and operable to receive a first reference voltage on the supply node and to electrically isolate the memory line from the supply node during the programming cycle, the erasing path further including a number of transistors serially coupled between the memory line and the supply node, each transistor having a breakdown voltage that is no less than a pre-established breakdown voltage, the number of transistors being greater than or equal to a ratio of the difference between the programming and reference voltages to the pre-established breakdown voltage.

26. The system of claim 25 wherein the controller and memory are disposed on a same integrated circuit.

27. The system of claim 25 wherein the controller and memory are disposed on respective integrated circuits.

28. A method, comprising:
driving a programming voltage onto a selected memory line;
driving a reference voltage onto an unselected memory line;
while driving the programming voltage onto the memory line, electrically isolating the selected memory line from the reference voltage with an erasing circuit having a number of transistors serially coupled between the selected memory line and the reference voltage, each transistor having a breakdown voltage that is no less than a pre-established breakdown voltage, the number of transistors being greater than or equal to a ratio of the difference between the programming and reference voltages to the pre-established breakdown voltage.

29. The method of claim 28, further comprising biasing a control node of each transistor such that no voltage across the control node and any conduction node of the transistor exceeds the pre-established breakdown voltage during the programming cycle.

30. The method of claim 28, further comprising biasing a control node of each transistor such that no voltage across any two nodes of the transistor exceeds the pre-established breakdown voltage during the programming cycle.
